(19) United States
(12) Patent Application Publication
(10) Pub. No.: US 2024/0234130 A1
(43) Pub. Date: Jul. 11, 2024

(54) HIGH QUALITY INSITU TREATED PECVD FILM

(71) Applicant: Texas Instruments Incorporated, Dallas, TX (US)

(72) Inventors: SK Saiful Islam, Lehi, UT (US); Gowrisankar Damarla, Lehi, UT (US)

(21) Appl. No.: 18/161,045

(22) Filed: Jan. 28, 2023

Related U.S. Application Data
(60) Provisional application No. 63/479,277, filed on Jan. 10, 2023.

(51) Int. Cl. H01L 21/02; C23C 16/40; C23C 16/455; C23C 16/56

(52) U.S. Cl. CPC H01L 21/02274; C23C 16/401; C23C 16/45536; C23C 16/45553; C23C 16/56; H01L 21/0228

(57) ABSTRACT

A method of fabricating an electronic device includes performing a plasma enhanced pretreatment process in a deposition chamber to pretreat a surface, performing a first plasma enhanced deposition process in the deposition chamber to deposit a first oxide of an oxide layer to a first thickness on the surface, performing an in situ first plasma enhanced treatment process in the deposition chamber to treat the first oxide of the oxide layer, performing one or more loop iterations of a second plasma enhanced deposition process in the deposition chamber to deposit a second or further oxide on the first oxide and increase the oxide layer thickness, and an in situ second plasma enhanced treatment process in the deposition chamber to treat the second or further oxide of the oxide layer.

### CROSS-REFERENCE TO RELATED APPLICATION

This application claims priority to and benefit of U.S. Provisional Patent Application Ser. No. 63/479,277, filed on Jan. 10, 2023, and titled “High Quality Highly Conformal ALD Like PECVD Film with superior electrical performance”, the contents of which are hereby fully incorporated by reference.

### BACKGROUND

Single wafer, high temperature processing chambers can be used to form films such as oxide layers on a surface during wafer processing in the manufacture of electronic devices, but these are expensive tools and are limited with respect to throughput. Moreover, improvements are desirable in the quality and conformality of oxide films.

### SUMMARY

In one aspect, an electronic device includes an oxide layer having silicon and oxygen, the oxide layer having an atomic percentage of oxygen of greater than 64 percent by weight and an atomic percentage of carbon of less than 1 percent by weight.

In another aspect, a method of fabricating an electronic device includes: performing a plasma enhanced pretreatment process in a deposition chamber to pretreat a surface; performing a first plasma enhanced deposition process in the deposition chamber to deposit a first oxide of an oxide layer to a first thickness on the surface; performing an in situ first plasma enhanced treatment process in the deposition chamber to treat the first oxide of the oxide layer; performing a second plasma enhanced deposition process in the deposition chamber to deposit a second oxide on the first oxide and increase the oxide layer to a second thickness; and performing an in situ second plasma enhanced treatment process in the deposition chamber to treat the second oxide of the oxide layer.

### BRIEF DESCRIPTION OF THE DRAWINGS

FIG. 1 is a partial sectional side elevation view of an electronic device with a high quality oxide layer.

FIG. 1A is a partial view showing further details of a gate sidewall layer structure in the electronic device of FIG. 1.

FIG. 1B is a perspective view of the packaged electronic device of FIGS. 1 and 1A.

FIG. 2 is a flow diagram of a method of fabricating an electronic device with an oxide layer.

FIGS. 3A-3K and 4 are partial sectional side elevation views of the electronic device of FIGS. 1-1B undergoing fabrication processing to form a transistor offset sidewall spacer oxide layer according to the method of FIG. 2.

FIGS. 5A-5K and 6 are partial sectional side elevation views of the electronic device of FIGS. 1-1B undergoing fabrication processing to form a transistor cap oxide layer according to the method of FIG. 2.

FIGS. 7A-7K, 8A and 8B are partial sectional side elevation views of the electronic device of FIGS. 1-1B undergoing fabrication processing to form and use a gate etch oxide hard mask layer according to the method of FIG. 2.

FIGS. 9A-9K, 10A and 10B are partial sectional side elevation views of the electronic device of FIGS. 1-1B undergoing fabrication processing to form and use a trench etch hard mask oxide layer according to the method of FIG. 2.

FIGS. 11A-11K, and 12 are partial sectional side elevation views of the electronic device of FIGS. 1-1B undergoing fabrication processing to form and use a front side protection layer according to the method of FIG. 2.

FIG. 13 is a graph of Fourier-transform infrared spectroscopy (FTIR) spectra for an example oxide layer fabricated according to an implementation of the method of FIG. 2.

FIG. 14 is a table of atomic percentages for an example oxide layer fabricated according to an implementation of the method of FIG. 2.

FIG. 15 is a plot of comparative flash memory electrical performance for an example oxide layer fabricated according to an implementation of the method of FIG. 2 and a single wafer high temperature oxide layer (SW HTO).

FIG. 16 is a plot of comparative transistor drive current performance for an example oxide layer fabricated according to an implementation of the method of FIG. 2 and a SW HTO layer.

FIG. 17 is a plot of comparative transistor gate-drain capacitance performance for an example oxide layer fabricated according to an implementation of the method of FIG. 2 and a SW HTO layer.

FIG. 18 is a plot of comparative transistor drive current performance for an example oxide layer fabricated according to an implementation of the method of FIG. 2 and a SW HTO layer.

FIG. 19 is a plot of comparative transistor gate-drain capacitance performance for an example oxide layer fabricated according to an implementation of the method of FIG. 2 and a SW HTO layer.

FIG. 20 is a plot of comparative transistor drive current performance for an example oxide layer fabricated according to an implementation of the method of FIG. 2 and a SW HTO layer.

FIG. 21 is a plot of comparative transistor drive current performance for an example oxide layer fabricated according to an implementation of the method of FIG. 2 and a SW HTO layer.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means+/−10 percent of the stated value and “substantially no” means zero or no measurable amount that reasonably affects quality or operation of a finished product or effectivity of a process. The example structures include layers or materials described as over or on another layer or material or surface, which can be a layer or material directly on and contacting the other layer or material or surface where other materials, such as impurities or artifacts or remnant materials from fabrication processing may be present between the layer or material and the other layer or material or surface.

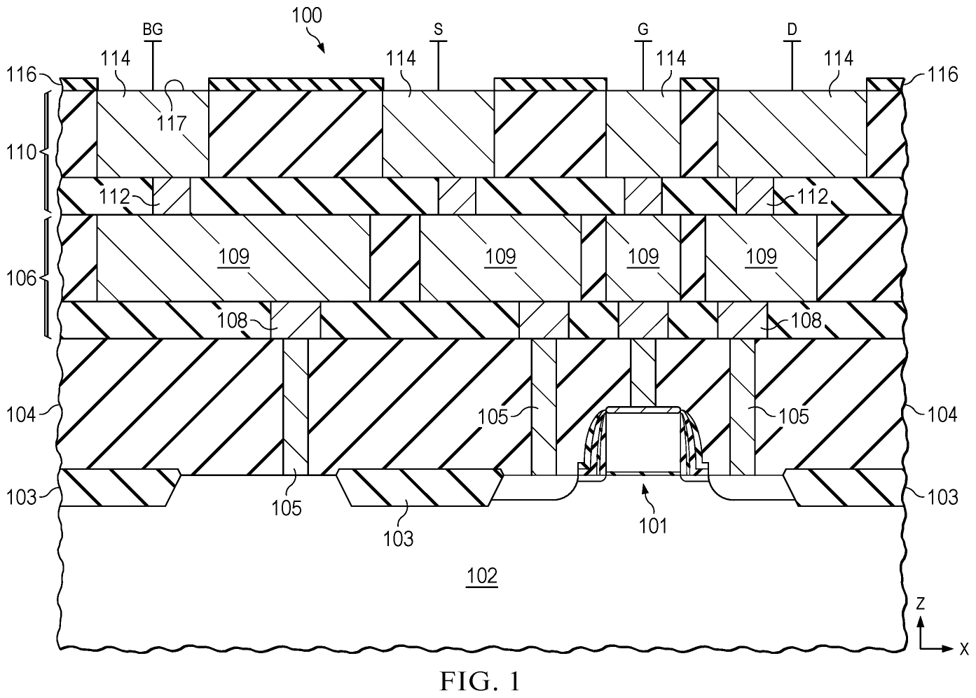

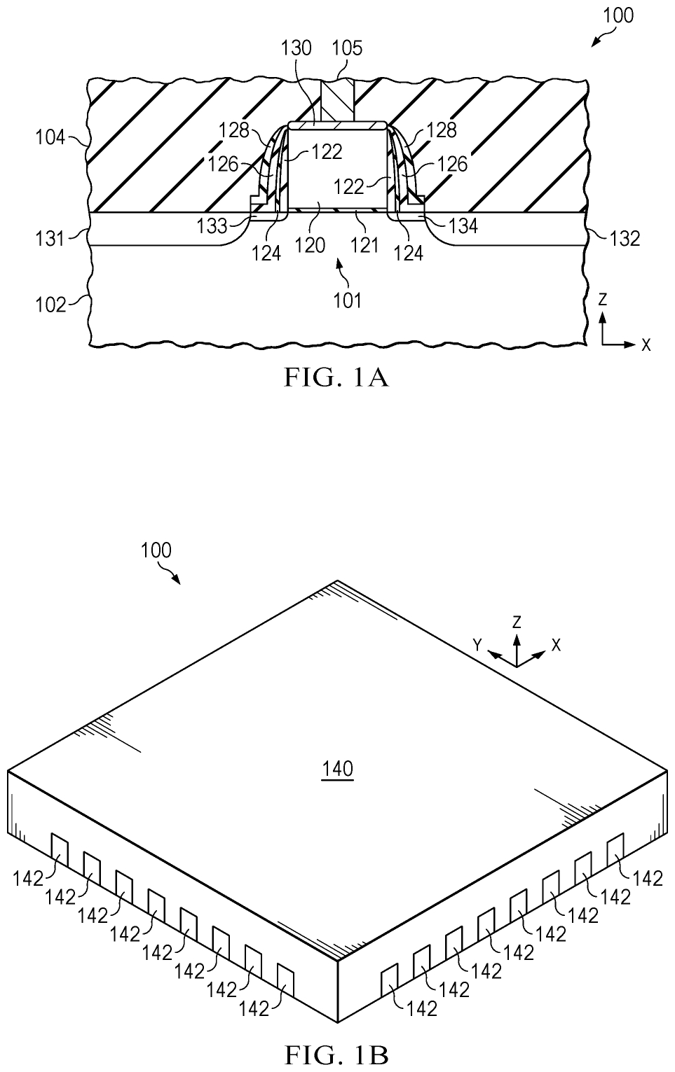

FIGS. 1-1B show a packaged electronic device 100 with at least one high quality oxide layer. FIG. 1 shows a partial side view of the electronic device 100, FIG. 1A shows further details of a gate sidewall layer structure in the electronic device 100 and FIG. 1B shows a perspective view of the packaged electronic device 100. The electronic device 100 is shown in FIGS. 1-1B in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. As shown in FIG. 1B, the electronic device 100 has opposite first and second (e.g., bottom and top) sides which are spaced apart from one another along the third direction Z. The electronic device 100 also has laterally opposite third and fourth sides spaced apart from one another along the first direction X, and opposite fifth and sixth sides spaced apart from one another along the second direction Y in the illustrated orientation. The sides in one example have substantially planar outer surfaces. In other examples, one or more of the sides have curves, angled features, or other non-planar surface features.

The electronic device 100 includes a transistor 101 formed on and/or in a semiconductor substrate 102 (e.g., silicon, gallium nitride, silicon carbide, silicon-on-insulator (SOI), etc.). The electronic device 100 in one example includes a single transistor 101. In other implementations, the electronic device 100 can be an integrated circuit that includes multiple electronic components. As shown in FIG. 1, the electronic device 100 includes a multilayer metallization structure with multiple conductive features that are respectively electrically connected to corresponding terminals (source “S”, drain “D”, gate “G”, and a back gate contact BG) of the transistor 101. The example electronic device 100 also includes isolation structures 103 disposed on select portions of an upper surface or side of the substrate 102. The isolation structures 103 in the illustrated example are shallow trench isolation (STI) features. In other examples, field oxide (FOX) isolation structures can be used.

The example electronic device 100 also includes a multilayer metallization structure disposed above the substrate 102. The metallization structure includes a first dielectric structure layer 104 formed over the substrate 102, as well as a multilevel upper metallization structure. In one example, the first dielectric structure layer 104 is a pre-metal dielectric (PMD) layer disposed over the transistor 101, the isolation structures 103, and the upper surface of the substrate 102. In one example, the first dielectric structure layer 104 includes silicon dioxide (SiO₂) deposited over the transistor 101, the substrate 102 and the isolation structures 103. The metallization structure includes tungsten plugs or contacts 105 that extend from various terminals of the transistor 101 through the PMD layer 104, as well as overlying dielectric layers 106 and 110, referred to herein as interlayer or interlevel dielectric (ILD) layers. Different numbers of layers can be used in different implementations. In one example, the first ILD layer 106 and the final ILD layer 110 are formed of silicon dioxide (SiO₂) or other suitable dielectric material. In certain implementations, the individual layers of the multi-layer upper metallization structure are formed in two stages, including an intra-metal dielectric (IMD, not shown) sublayer and an ILD sublayer overlying the IMD sublayer. The individual IMD and ILD sublayers can be formed of any suitable dielectric material or materials, such as SiO₂-based dielectric materials. The first ILD layer 106 and the upper ILD layer 110 include respective conductive vias 108 and 112, such as copper, tungsten, aluminum, etc. The vias 108 and 112 in this example provide electrical connection from the metallization features of successive layers, for example, to connect lines of an individual layer to an overlying metallization layer. The metallization structure in this example also includes metal layers, referred to as conductive lines 109 and 114, for routing in the respective layers 106 and

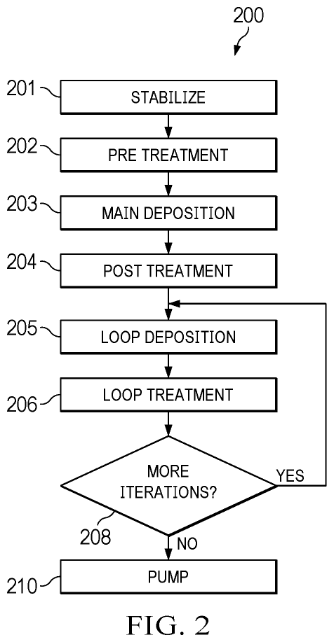

In one implementation, the vias 112 and the line metal layers 114 in the upper metallization layer 110 are formed using a dual damascene process, where the metal via 112 and the metal lines 114 are formed as a unitary multilayer structure. In one example, the upper ILD dielectric layer 110 in one example is covered by one or more passivation layers 116 (e.g., protective overcoat (PO) and/or passivation layers), for example, silicon nitride (SiN), silicon oxynitride (SiOₓN_{y}), or silicon dioxide (SiO₂). In one example, the passivation layer or layers 116 include one or more openings that expose a portion of the metal layers 114 to allow electrical connection of the metal layers 114 to corresponding contacts or conductive features (e.g., conductive pillars, solder bumps, etc., not shown), or to allow soldering to bond wires (not shown). The substrate 102, the transistor 101, the first dielectric structure layer 104 and the upper metallization structure 106, 110 form the electronic device 100 with an upper side or surface 117. The example in FIGS. 1 and 2 is shown as a unitary wafer structure prior to die separation or singulation. The top metallization layer 110 includes example metal layers 114, such as upper most copper lines or pads with exposed upper sides or surfaces at an upper side 117 of the electronic device 100 at the top of the uppermost metallization layer 110. Any number of exposed metal layers 114 may be provided. Some of the metal layers 114 are electrically coupled with the transistor 101 through the metallization structure of the electronic device 100.

FIG. 1A shows further details of the transistor 101 including a gate sidewall layer structure in the electronic device 100. In this example, the transistor 101 has a gate structure with a polysilicon gate 120 on a gate oxide layer 121, as well as a gate sidewall structure including a transistor offset sidewall spacer oxide layer 122, a nitride layer 124 on the offset sidewall spacer oxide layer 122, a transistor cap oxide layer 126 on the nitride layer 124, and a second nitride layer 128 on the cap oxide layer 126. A silicide contact 130 extends on a top side of the polysilicon gate 120 and is coupled to the associated tungsten contact 105 as shown in FIG. 1A, which also shows portions of respective first and second implanted source/drain regions 131 and 132 and first and second lightly doped drain (LDD) implanted regions 133 and 134, respectively. FIG. 1B shows an example of the packaged electronic device 100 with a molded package structure 140 and conductive leads 142. In one example, a semiconductor die including the transistor 101 is mounted on a die attach pad or routable lead frame (not shown) and electrical connections are made to the transistor 101 by bond wires (not shown) or through lead frame signal routing to connect one or more of the transistor terminals to respective ones of the conductive leads 142 of the packaged electronic device 100.

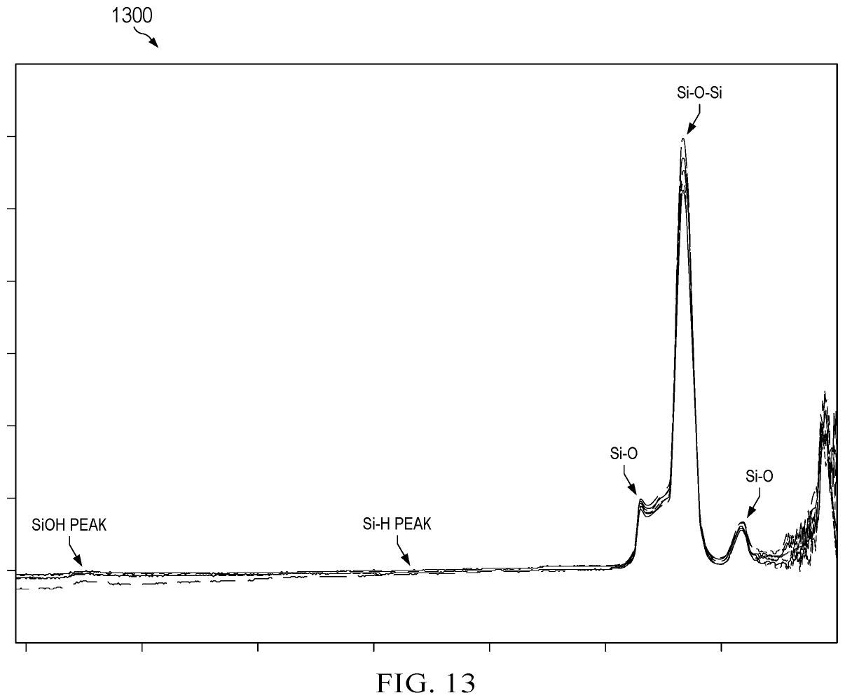

One or both of the oxide sidewall offset spacer and cap layers 122 and 126 in this example are high quality silicon dioxide films (e.g., SiₓO_{y}) of any suitable stoichiometry (e.g., where y is approximately 2×), referred to as high quality in situ treated oxide (referred to as HQITOX oxide). In one example, one or both of the oxide layers 122 and 126 have an atomic percentage of oxygen of greater than 64 percent by weight, such as approximately 65.6 percent by weight, and an atomic percentage of carbon of less than 1 percent by weight. In these or another example, one or both of the oxide layers 122 and 126 operate during fabrication as diffusion barriers to implanted dopants, for example, boron dopants of the implanted regions 131-134 for a p-channel or pmos implementation of the transistor 101 or phosphorus dopants for an n-channel or nmos transistor 101, and one or both of the oxide layers 122 and 126 of the finished electronic device 100 have little or no diffused dopants therein. In the above or other examples, one or both of the oxide layers 122 and 126 have no detectable or measurable carbon (e.g., 0 atomic percentage by weight). In the above or other examples, one or both of the oxide layers 122 and 126 have an atomic percentage of silicon of approximately 34.4 percent by weight. In the above or other examples, one or both of the oxide layers 122 and 126 have an atomic percentage of silicon-oxygen bonds (e.g., Si—O) of approximately 33.1 percent by weight. In the above or other examples, one or both of the oxide layers 122 and 126 are formed on an underlying surface by the process or method 200 described below in connection with FIG. 2. FIGS. 13-21 below illustrated properties and advantages of certain example implementations of the transistor 101 and/or one or both the oxide layers 122 and 126.

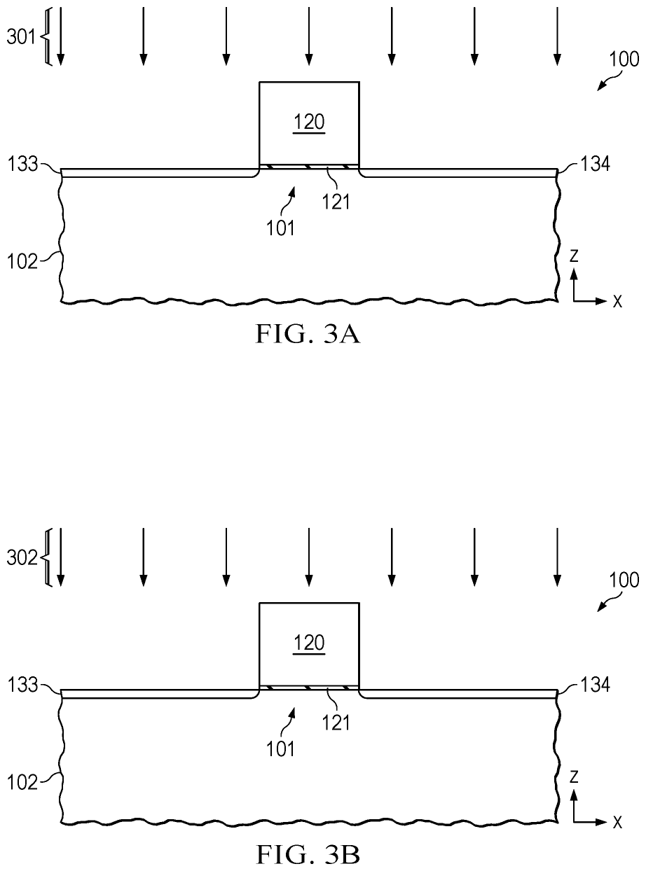

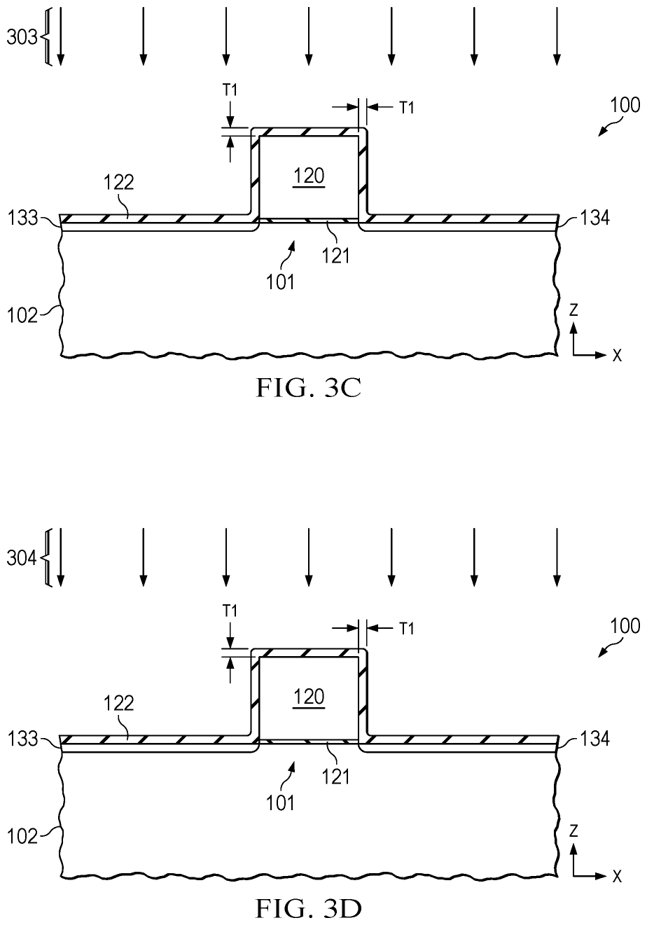

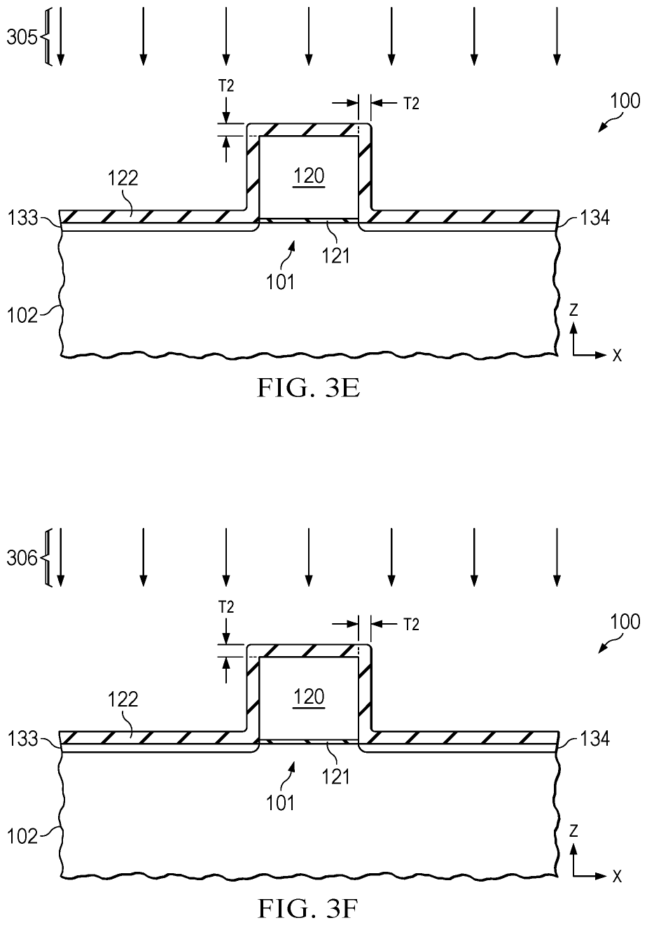

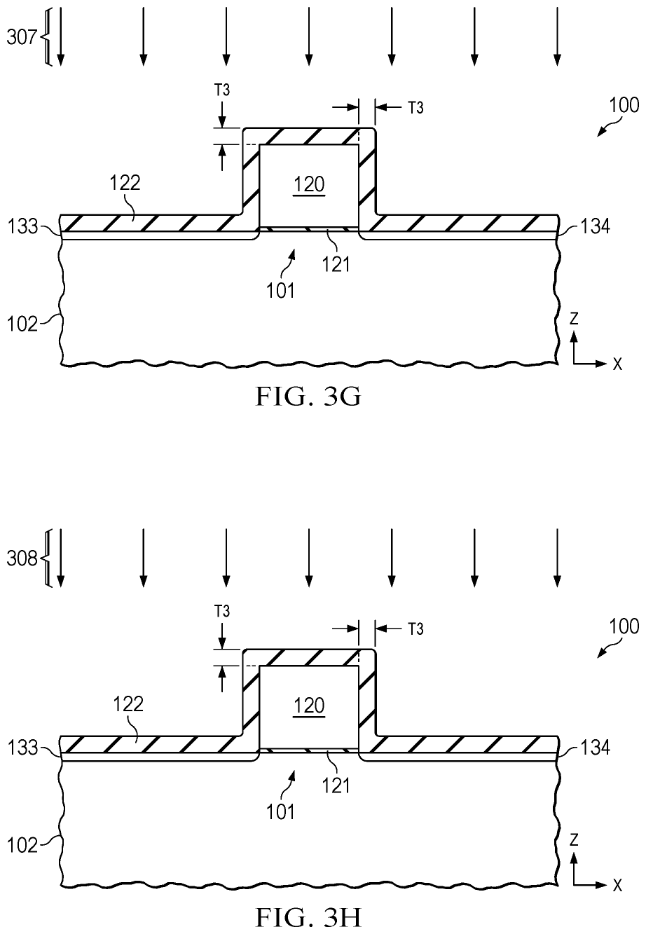

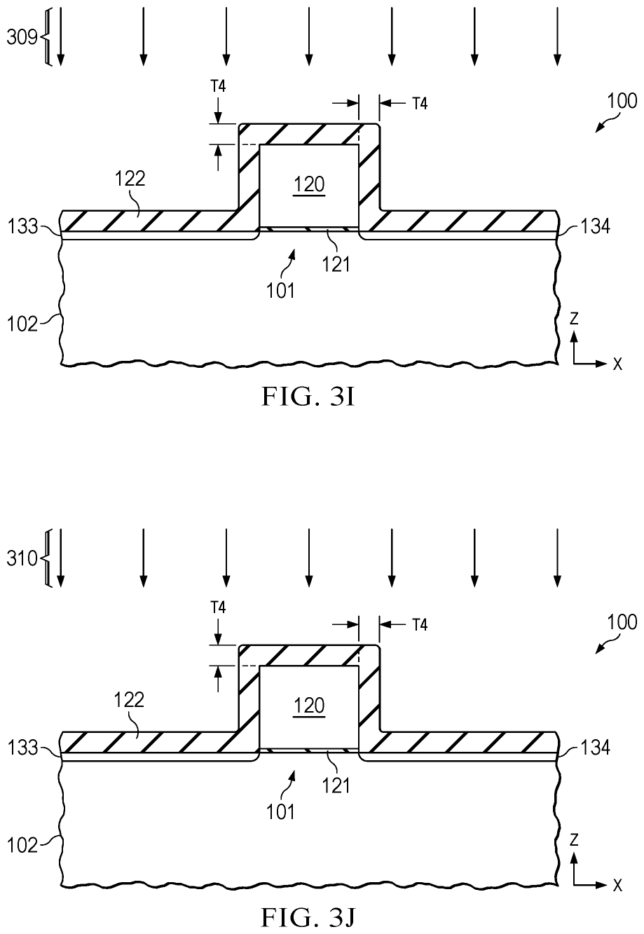

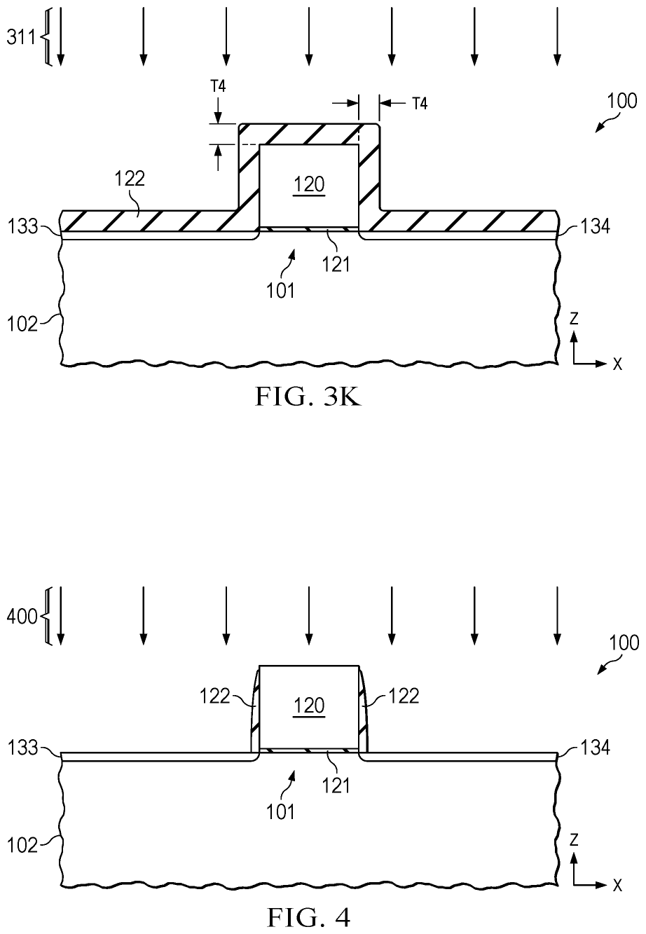

Referring now to FIGS. 2 and 3A-4, FIG. 2 shows an example method 200 of fabricating an electronic device with an oxide layer, and FIGS. 3A-3K and 4 show the electronic device 100 undergoing fabrication processing to form an implementation of the transistor offset sidewall spacer oxide layer 122 according to an example implementation of the method 200. The illustrated examples for oxide layers using an oxygen precursor gas and a silicon precursor gas (e.g., silane or SiH₄). In other examples, different implementations of the method 200 can be performed to form other oxide films, for example, using different kinds of precursor gasses, such as a silane silicon precursor, TSA precursor (e.g., Trichostatin A (TSA), C₁₇H₂₂N₂O₃), nitrosilane precursor (e.g., NO₂Si), TMS precursor (e.g., Tetramethylsilane (abbreviated as TMS), C₄H₁₂Si), and an oxygen precursor (e.g., O₂, N₂O, etc.).

The method 200 in the illustrated example is implemented as a continuous in situ process in a single environmentally controlled deposition chamber of a plasma enhanced chemical vapor deposition (PECVD) tool (not shown) that can accommodate one or more concurrently processed wafers. In the described examples, a semiconductor wafer (e.g., a silicon, gallium nitride, silicon carbide, silicon-on-insulator (SOI) wafer, etc.) is installed in the deposition chamber and the chamber is sealed and chamber pressure and chamber temperature are allowed to stabilize at 201. FIG. 3A shows one example, in which a wafer is installed in the deposition chamber and a process 301 is performed to stabilize the environmental conditions inside the chamber. The wafer may have undergone previous processing in the same chamber or in/at another semiconductor fabrication processing tool, and the illustrated method 200 provides for formation of an oxide layer on a surface, such as a semiconductor surface of the wafer and/or a surface of one or more previously formed layers.

In the example of FIGS. 3A-3K, the method 200 is performed to form an example implementation of the offset sidewall spacer oxide layer 122 of the transistor 101 on the exposed surfaces of the polysilicon gate structure 120, the gate oxide layer 121 and the top side of the semiconductor substrate 102 including the previously implanted LDD regions 133 and 134 shown in FIG. 3A by plasma enhanced chemical vapor deposition with in situ treatment and one or more iterations of loop deposition and loop treatments. In the illustrated implementation, the method 200 is performed as a continuous process with controlled phases or stages and adjustment of process gas flows and controlled chamber temperature and pressure. In one example, the offset sidewall spacer oxide layer 122 is a relatively thin oxide layer formed by a main deposition to a first thickness T1 (e.g., approximately 60 angstroms), followed by a post treatment and a small number (e.g., three) of one or more loop deposition and loop treatments that add additional incremental amounts (e.g., approximately 10 angstroms or more and approximately 40 angstroms or less) to increase the thickness of the offset sidewall spacer oxide layer 122 to a desired final thickness (e.g., approximately 80 angstroms or more and approximately 250 angstroms or less).

At 202 in FIG. 2, the method 200 includes performing a plasma enhanced pretreatment process, also referred to as a pre treatment or pretreat step or phase or stage, in the deposition chamber to pretreat the surface on which the oxide layer 122 is to be formed. The plasma enhanced pretreatment process in some examples uses low RF power to protect the surface and facilitate adhesion of the new oxide film to the existing surface of a previous layer or substrate. The pretreatment process also preheats the surface with plasma and inert gas to facilitate outgassing and introduces some oxygen to facilitate adhesion of the subsequently deposited layer.

FIG. 3B shows one example, in which a plasma enhanced pretreatment process 302 is performed that pretreats the exposed surfaces. In one implementation, the plasma enhanced pretreatment process 302 includes concurrent flows of an inert gas (e.g., helium (He), argon (Ar), etc.) at a non-zero flow rate (e.g., 500 to 25,000 standard cubic centimeters per minute (sccm or cm³/m) such as approximately 1,000 sccm) and an oxygen precursor (e.g., nitrous oxide (N₂O)) at a non-zero flow rate (e.g., 500 to 15,000 sccm, such as approximately 4,000 sccm) at a first radio frequency (RF) power level (e.g., 75 to 550 W, such as approximately 120 W) and a first chamber pressure (e.g., 2 to 11 Torr, such as approximately 3 Torr) and a first chamber temperature (e.g., 150 to 550 degrees C., such as approximately 350 degrees C.). In the above or other examples, the plasma enhanced pretreatment process 302 includes substantially no flow of silicon precursor.

The method 200 continues with a first plasma enhanced deposition, referred to as a main deposition phase at 203 in FIG. 2. FIG. 3C shows one example, in which a first plasma enhanced deposition process 303 is performed in the deposition chamber, which deposits a first oxide of the oxide layer 122 to a first thickness T1 (e.g., approximately 60 angstroms) on the exposed surface of the polysilicon gate structure 120, the gate oxide layer 121 and the top side of the semiconductor substrate 102 including the previously implanted LDD regions 133 and 134. The first plasma enhanced deposition in the illustrated example has a low deposition rate compared to previous single wafer high temperature oxide (SW HTO) processes which facilitates high film quality with little or no contaminants in the film material. In addition, the resulting deposited oxide layer 122 has good conformality, where the first thickness T1 is uniform along the top surfaces of the polysilicon gate structure 120 and on the top surface of the semiconductor substrate 102, and the oxide layer 122 has approximately the same lateral thickness T1 along the sidewalls of the polysilicon gate structure 120 (e.g., conformality of approximately 95 percent or more compared with approximately 50 percent conformality for conventional PECVD oxide layers).

In one example, the first plasma enhanced deposition process 303 is a PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a second RF power level (e.g., 75 to 550 W, such as approximately 100 W) and a second chamber pressure (e.g., 2 to 11 Torr, such as approximately 3 Torr). In one example, the second chamber pressure is greater than the first chamber pressure. In this or another example, a ratio of the flow rate of the silicon precursor (e.g., SiH₄) to a flow rate of the oxygen precursor (e.g., N₂O) in the first plasma enhanced deposition process 303 is approximately 0.5 or less. In the above or another example, the ratio of the flow rate of the silicon precursor (e.g., SiH₄) to the flow rate of the oxygen precursor (e.g., N₂O) in the first plasma enhanced deposition process 303 is approximately 0.0002 or more. In the above or another example, the ratio of the flow rate of the silicon precursor (e.g., SiH₄) to the flow rate of the oxygen precursor (e.g., N₂O) in the first plasma enhanced deposition process 303 is approximately 0.0025. In the above or another example, the flow rate of the silicon precursor (e.g., SiH₄) in the first plasma enhanced deposition process 303 is approximately 2 sccm or more and approximately 50 sccm or less, such as approximately 25 sccm.

The method 200 continues with an in situ first plasma enhanced treatment process at 204 in FIG. 2, also referred to as a post treatment or post-treat phase. FIG. 3D shows one example, in which an in situ first plasma enhanced treatment process 304 is performed in the deposition chamber to treat the first oxide of the oxide layer 122. In one example, the first plasma enhanced treatment process 304 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a third RF power level (e.g., 75 to 550 W, such as approximately 225 W) that is greater than the first and second power levels and at a third chamber pressure (e.g., 2 to 11 Torr, such as approximately 3 Torr). In one example, the first plasma enhanced treatment process 304 includes substantially no flow of the silicon precursor.

The method 200 continues with a second plasma enhanced deposition process at 205 in FIG. 2, also referred to as a loop deposition. FIG. 3E shows one example, in which a second plasma enhanced deposition process 305 is performed in the deposition chamber to deposit a second oxide on the first oxide and increase the oxide layer 122 to a second thickness T2. The oxide layer 122 after the second plasma enhanced deposition process 305 has good conformality where the second thickness T2 is uniform along the top surfaces of the polysilicon gate structure 120 and on the top surface of the semiconductor substrate 102, and the oxide layer 122 has approximately the same lateral thickness T2 along the sidewalls of the polysilicon gate structure 120 (e.g., conformality of approximately 95 percent or more). In one example, the second plasma enhanced deposition process 305 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the second plasma enhanced deposition process 305 is approximately 0.5 or less. In the above or another example, the ratio of the flow rate of the silicon precursor (e.g., SiH₄) to the flow rate of the oxygen precursor (e.g., N₂O) in the second plasma enhanced deposition process 305 is approximately 0.0002 or more. In the above or another example, the ratio of the flow rate of the silicon precursor (e.g., SiH₄) to the flow rate of the oxygen precursor (e.g., N₂O) in the second plasma enhanced deposition process 305 is approximately 0.0025. In the above or another example, the flow rate of the silicon precursor (e.g., SiH₄) in the second plasma enhanced deposition process 305 is approximately 2 sccm or more and approximately 50 sccm or less, such as approximately 25 sccm.

The method 200 continues with an in situ second plasma enhanced treatment process at 206, referred to as a loop treatment or loop treat. FIG. 3F shows one example, in which an in situ second plasma enhanced treatment process 306 is performed in the deposition chamber to treat the second oxide of the oxide layer 122. The second plasma enhanced treatment process 306 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fourth RF power level (e.g., 75 to 550 W, such as approximately 225 W) that is greater than the first and second power levels and at a fourth chamber pressure (e.g., 2 to 11 Torr, such as approximately 3 Torr). In one example, the second plasma enhanced treatment process 306 includes substantially no flow of the silicon precursor.

The method 200 continues in FIG. 2 after the second plasma enhanced treatment process with one or more iterations of the loop deposition and loop treatments at 205 and 206 to achieve a desired final oxide layer thickness. If more iterations are needed (YES at 208), the method 200 returns to 205 for a third plasma enhanced deposition process (e.g., a further loop iteration, also referred to as a further loop deposition). FIG. 3G shows one example, in which a third plasma enhanced deposition process 307 is performed in the deposition chamber that deposits a third oxide on the second oxide and increases the oxide layer 122 to a third thickness T3. The oxide layer 122 after the third plasma enhanced deposition process 307 has good conformality where the third thickness T3 is uniform along the top surfaces of the polysilicon gate structure 120 and on the top surface of the semiconductor substrate 102, and the oxide layer 122 has approximately the same lateral thickness T3 along the sidewalls of the polysilicon gate structure 120 (e.g., conformality of approximately 95 percent or more). In one example, the third plasma enhanced deposition process 307 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the third plasma enhanced deposition process 307 is approximately 0.5 or less. In the above or another example, the ratio of the flow rate of the silicon precursor (e.g., SiH₄) to the flow rate of the oxygen precursor (e.g., N₂O) in the third plasma enhanced deposition process 307 is approximately 0.0002 or more. In the above or another example, the ratio of the flow rate of the silicon precursor (e.g., SiH₄) to the flow rate of the oxygen precursor (e.g., N₂O) in the third plasma enhanced deposition process 307 is approximately 0.0025. In the above or another example, the flow rate of the silicon precursor (e.g., SiH₄) in the third plasma enhanced deposition process 307 is approximately 2 sccm or more and approximately 50 sccm or less, such as approximately 25 sccm.

The method 200 continues with an in situ third plasma enhanced treatment process at 206, referred to as a loop treatment or loop treat. FIG. 3H shows one example, in which an in situ third plasma enhanced treatment process 308 is performed in the deposition chamber to treat the third oxide of the oxide layer 122. The third plasma enhanced treatment process 308 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fifth RF power level (e.g., 75 to 550 W, such as approximately 225 W) that is greater than the first and second power levels and at a fourth chamber pressure (e.g., 2 to 11 Torr, such as approximately 3 Torr). In one example, the third plasma enhanced treatment process 308 includes substantially no flow of the silicon precursor.

If a further loop deposition and treatment iteration is needed to achieve a desired oxide layer thickness (YES at 208) in FIG. 2, the method 200 returns to 205 for a fourth plasma enhanced deposition process (e.g., a further loop iteration, also referred to as a further loop deposition). FIG. 3I shows one example, in which a fourth plasma enhanced deposition process 309 is performed in the deposition chamber that deposits a fourth oxide on the third oxide and increases the oxide layer 122 to a fourth thickness T4. The oxide layer 122 after the fourth plasma enhanced deposition process 309 has good conformality where the fourth thickness T4 is uniform along the top surfaces of the polysilicon gate structure 120 and on the top surface of the semiconductor substrate 102, and the oxide layer 122 has approximately the same lateral thickness T4 along the sidewalls of the polysilicon gate structure 120 (e.g., conformality of approximately 95 percent or more). In one example, the fourth plasma enhanced deposition process 309 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fifth RF power level (e.g., 75 to 550 W, such as approximately 100 W) that is less than the third power level and at a fifth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the fourth plasma enhanced deposition process 309 is approximately 0.5 or less. In the above or another example, the ratio of the flow rate of the silicon precursor (e.g., SiH₄) to the flow rate of the oxygen precursor (e.g., N₂O) in the fourth plasma enhanced deposition process 309 is approximately 0.0002 or more. In the above or another example, the ratio of the flow rate of the silicon precursor (e.g., SiH₄) to the flow rate of the oxygen precursor (e.g., N₂O) in the fourth plasma enhanced deposition process 309 is approximately 0.0025. In the above or another example, the flow rate of the silicon precursor (e.g., SiH₄) in the fourth plasma enhanced deposition process 309 is approximately 2 sccm or more and approximately 50 sccm or less, such as approximately 25 sccm.

The method 200 continues with an in situ fourth plasma enhanced treatment process at 206, referred to as a loop treatment or loop treat. FIG. 3J shows one example, in which an in situ fourth plasma enhanced treatment process 310 is performed in the deposition chamber to treat the fourth oxide of the oxide layer 122. The fourth plasma enhanced treatment process 310 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a sixth RF power level (e.g., 75 to 550 W, such as approximately 225 W) that is greater than the first and second power levels and at a sixth chamber pressure (e.g., 2 to 11 Torr, such as approximately 3 Torr). In one example, the fourth plasma enhanced treatment process 310 includes substantially no flow of the silicon precursor.

In the illustrated implementation, the three loop iterations provide the desired final oxide layer thickness T4 and no further iterations are needed (NO at 208 in FIG. 2). The method 200 in this case proceeds to 210 for a pumping operation, after which further fabrication processing steps (not shown) are performed to produce the above described packaged electronic device 100. FIG. 3K shows one example, in which a pumping process 311 is performed that shuts off the various gas flows and pumps the chamber to remove any process remnants and prepares the wafer or wafers for removal from the deposition chamber. FIG. 4 shows one example of further processing by an etch process 400 that etches the deposited oxide layer 122 to expose the tops of the polysilicon gate structure 120 and the semiconductor substrate 102 with the thin sidewall spacer oxide layer 122 remaining along the lateral sidewalls of the polysilicon gate structure 120.

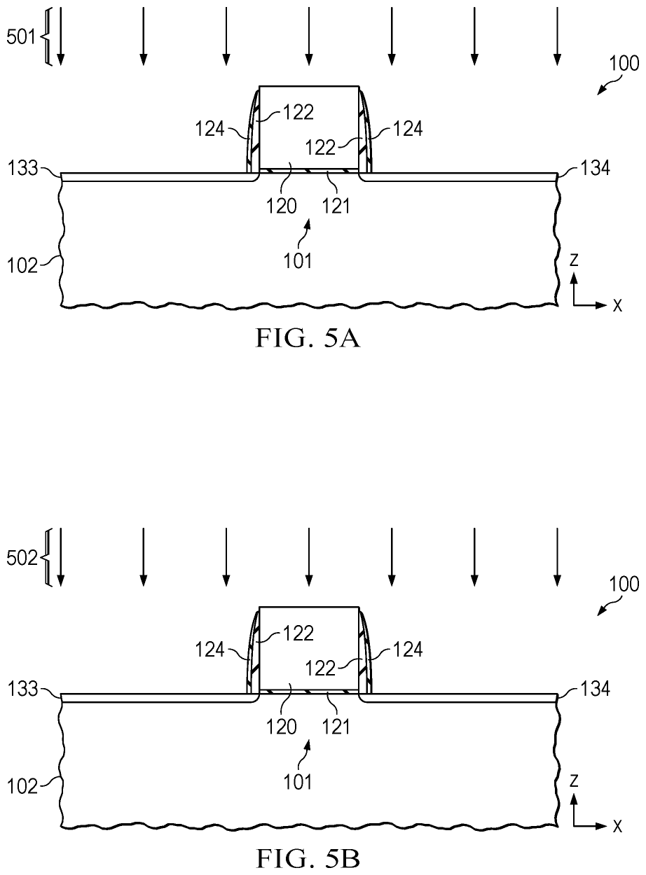

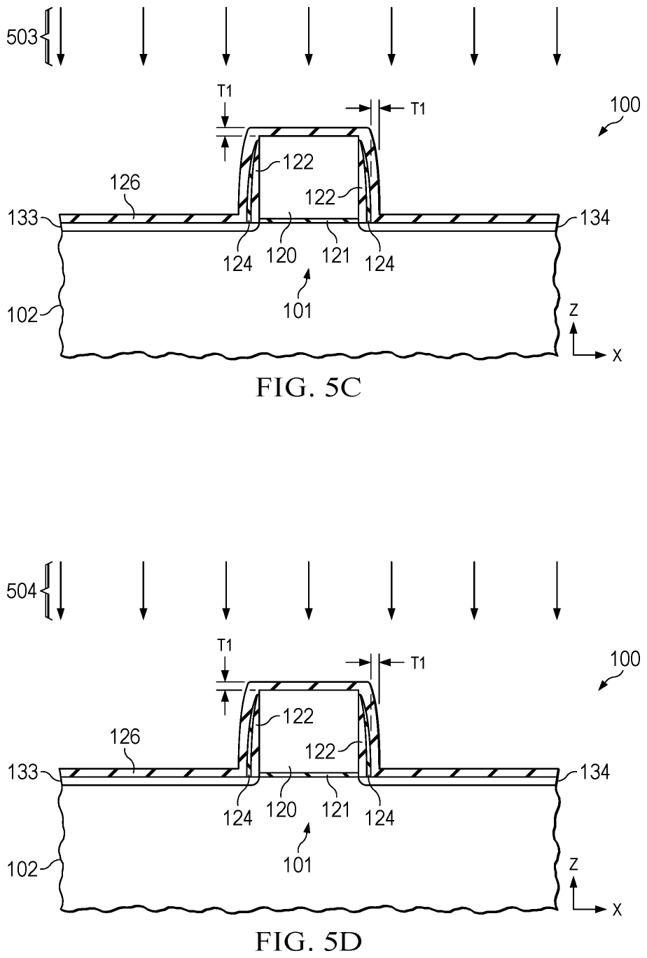

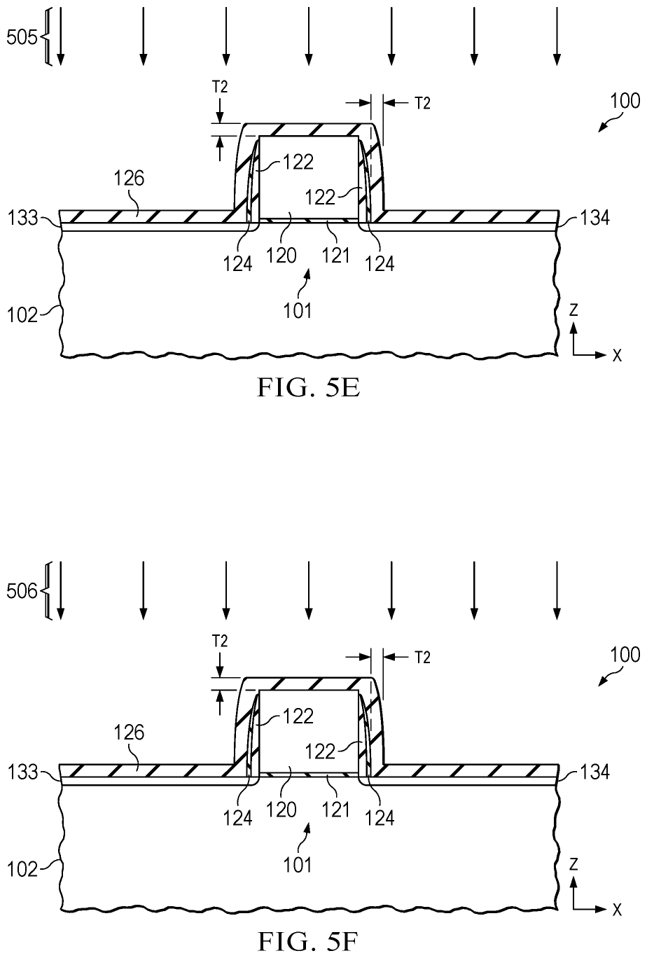

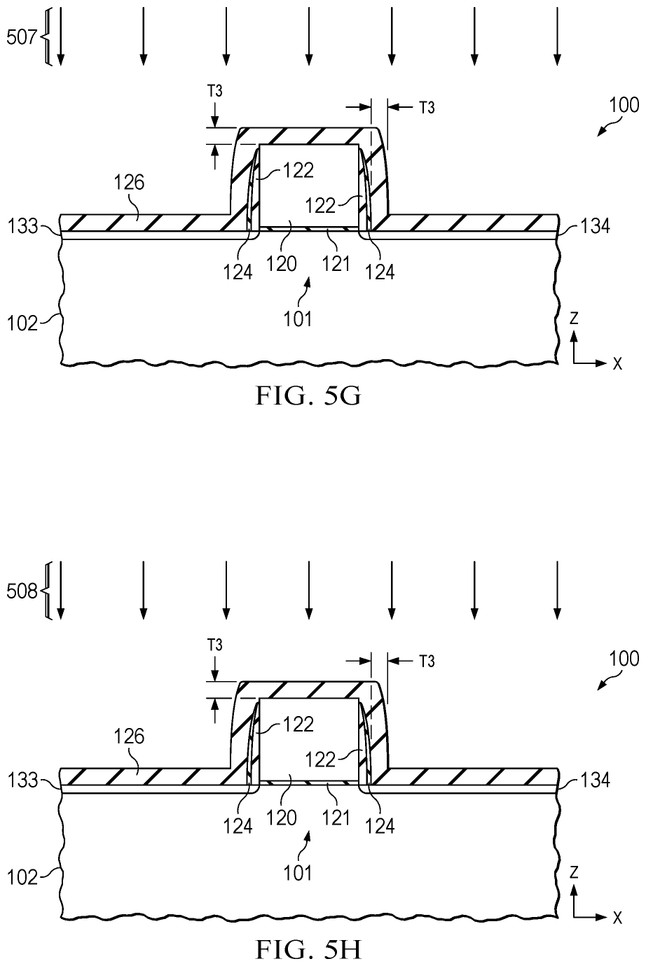

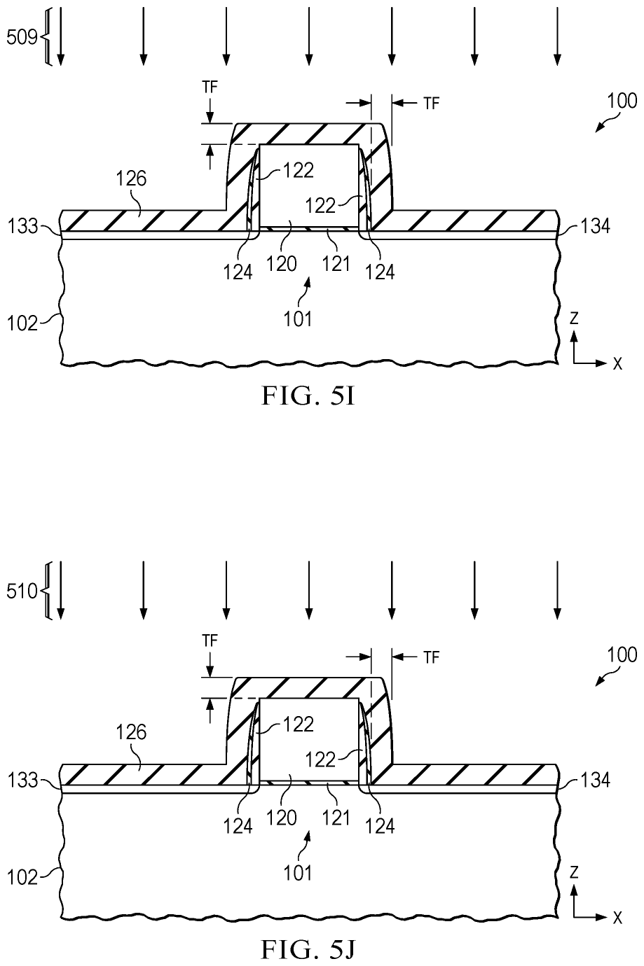

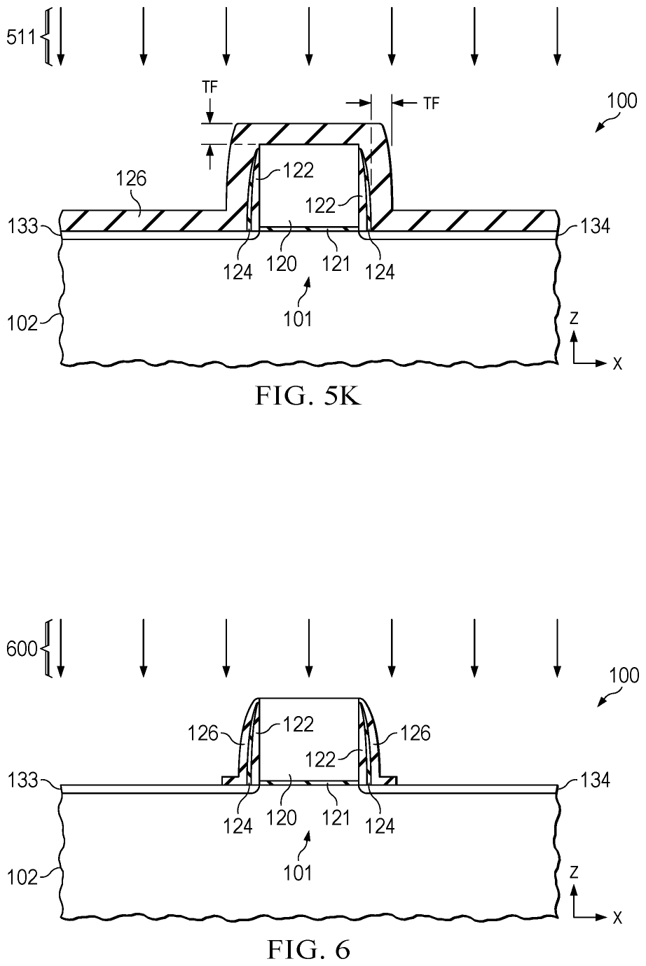

Referring also to FIGS. 5A-6, further processing (not shown) is performed in one example to form the nitride layer 124 on the sidewall spacer oxide layer 122 as shown in FIG. 5A, and another implementation of the method 200 in FIG. 2 is performed to form the cap oxide layer 126 described above in connection with FIG. 1A. In another example, the cap layer 126 may be formed by the method 200 of FIG. 2 without also forming the spacer oxide layer 122 by the method 200. The cap oxide layer 126 in this example is deposited to a larger desired thickness, and the implementation of the method 200 in this example includes creating a larger initial oxide layer thickness during the main deposition at 203 and more loop iterations at 205 and 206 compared to the example described above to form the thinner offset spacer oxide layer 122.

In the example of FIGS. 5A-5K, the method 200 is performed to form an example implementation of the cap oxide layer 126 of the transistor 101 on the exposed surfaces of the polysilicon gate structure 120, the nitride layer 124 and the top side of the semiconductor substrate 102 including the previously implanted LDD regions 133 and 134 shown in FIG. 5A by plasma enhanced chemical vapor deposition with in situ treatment and one or more iterations of loop deposition and loop treatments. In one example, the desired cap oxide layer 126 is a relatively thick oxide layer (e.g., SiₓO_{y}) of any suitable stoichiometry (e.g., where y is approximately 2×) formed by a main deposition to a first thickness T1 (e.g., approximately 100 angstroms), followed by a post treatment and a larger number (e.g., more than 5) of iterations of the loop depositions and loop treatments that add additional incremental amounts (e.g., approximately 30 angstroms or more and approximately 80 angstroms or less) to increase the thickness of the cap oxide layer 126 to a desired final thickness (e.g., approximately 200 angstroms or more and approximately 700 angstroms or less). The method 200 in this example is implemented as a continuous in situ process in a single environmentally controlled deposition chamber of a PECVD tool (not shown) that can accommodate one or more concurrently processed wafers, with controlled phases or stages and adjustment of process gas flows and controlled chamber temperature and pressure. The wafer or wafers are installed in the deposition chamber and the chamber is sealed and chamber pressure and chamber temperature are allowed to stabilize at 201. FIG. 5A shows one example, in which a wafer is installed in the deposition chamber and a stabilization process 501 is performed (e.g., 201 in FIG. 2 above) to stabilize the environmental conditions inside the chamber.

In FIG. 5B a plasma enhanced pretreatment process 502 is performed in the deposition chamber (e.g., 202 in FIG. 2) to pretreat the surface on which the oxide layer 126 is to be formed. The plasma enhanced pretreatment process 502 in some examples uses low RF power to protect the surface and facilitate adhesion of the new oxide film to the existing surface of a previous layer or substrate. The pretreatment process 502 also preheats the surface with plasma and inert gas to facilitate outgassing and introduces some oxygen to facilitate adhesion of the subsequently deposited layer. In one implementation, the plasma enhanced pretreatment process 502 includes concurrent flows of an inert gas (e.g., helium (He), argon (Ar), etc.) at a non-zero flow rate (e.g., 500 to 25,000 standard cubic centimeters per minute (sccm or cm³/m) such as approximately 1,000 sccm) and an oxygen precursor (e.g., nitrous oxide (N₂O)) at a non-zero flow rate (e.g., 500 to 15,000 sccm, such as approximately 4,000 sccm) at a first radio frequency (RF) power level (e.g., 75 to 550 W, such as approximately 120 W) and a first chamber pressure (e.g., 2 to 11 Torr, such as approximately 3 Torr) and a first chamber temperature (e.g., 150 to 550 degrees C., such as approximately 350 degrees C.). In the above or other examples, the plasma enhanced pretreatment process 502 includes substantially no flow of silicon precursor.

In FIG. 5C, a first plasma enhanced deposition process 503 is performed in the deposition chamber (e.g., a main deposition phase at 203 in FIG. 2). The first plasma enhanced deposition process 503 deposits a first oxide of the oxide layer 126 to a first thickness T1 (e.g., approximately 100 angstroms or more) on the exposed surface of the polysilicon gate structure 120, the nitride layer 124 and the top side of the semiconductor substrate 102 including the previously implanted LDD regions 133 and 134. The first plasma enhanced deposition in the illustrated example has a low deposition rate to facilitate high film quality with little or no contaminants in the film material. In addition, the resulting deposited oxide layer 126 has good conformality, where the first thickness T1 in FIG. 5C is uniform along the top surfaces of the polysilicon gate structure 120 and on the top surface of the semiconductor substrate 102, and the oxide layer 126 has approximately the same lateral thickness T1 along the sidewalls over the nitride layer 124 for a conformality of approximately 95 percent or more.

In one example, the first plasma enhanced deposition process 503 is a PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a second RF power level (e.g., 75 to 550 W, such as approximately 100 W) and a second chamber pressure (e.g., 2 to 11 Torr, such as approximately 3 Torr). In one example, the second chamber pressure is greater than the first chamber pressure. In this or another example, a ratio of the flow rate of the silicon precursor (e.g., SiH₄) to a flow rate of the oxygen precursor (e.g., N₂O) in the first plasma enhanced deposition process 503 is approximately 0.5 or less. In the above or another example, the ratio of the flow rate of the silicon precursor (e.g., SiH₄) to the flow rate of the oxygen precursor (e.g., N₂O) in the first plasma enhanced deposition process 503 is approximately 0.0002 or more. In the above or another example, the ratio of the flow rate of the silicon precursor (e.g., SiH₄) to the flow rate of the oxygen precursor (e.g., N₂O) in the first plasma enhanced deposition process 503 is approximately 0.0025. In the above or another example, the flow rate of the silicon precursor (e.g., SiH₄) in the first plasma enhanced deposition process 503 is approximately 2 sccm or more and approximately 50 sccm or less, such as approximately 25 sccm.

In FIG. 5D, an in situ first plasma enhanced treatment process 504 is performed in the deposition chamber (e.g., a post treatment or post-treat phase at 204 in FIG. 2) to treat the first oxide of the oxide layer 126. In one example, the first plasma enhanced treatment process 504 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a third RF power level (e.g., 75 to 550 W, such as approximately 225 W) that is greater than the first and second power levels and at a third chamber pressure (e.g., 2 to 11 Torr, such as approximately 3 Torr). In one example, the first plasma enhanced treatment process 504 includes substantially no flow of the silicon precursor.

In FIG. 5E, a second plasma enhanced deposition process 505 is performed in the deposition chamber (e.g., a loop deposition at 205 in FIG. 2) to deposit a second oxide on the first oxide and increase the oxide layer 126 to a second thickness T2. The oxide layer 126 after the second plasma enhanced deposition process 505 has good conformality where the second thickness T2 is uniform along the top surfaces of the polysilicon gate structure 120 and on the top surface of the semiconductor substrate 102, and the oxide layer 126 has approximately the same lateral thickness T2 along the sidewalls of the nitride layer 124 (e.g., conformality of approximately 95 percent or more). In one example, the second plasma enhanced deposition process 505 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the second plasma enhanced deposition process 505 is approximately 0.5 or less. In the above or another example, the ratio of the flow rate of the silicon precursor (e.g., SiH₄) to the flow rate of the oxygen precursor (e.g., N₂O) in the second plasma enhanced deposition process 505 is approximately 0.0002 or more. In the above or another example, the ratio of the flow rate of the silicon precursor (e.g., SiH₄) to the flow rate of the oxygen precursor (e.g., N₂O) in the second plasma enhanced deposition process 505 is approximately 0.0025. In the above or another example, the flow rate of the silicon precursor (e.g., SiH₄) in the second plasma enhanced deposition process 505 is approximately 2 sccm or more and approximately 50 sccm or less, such as approximately 25 sccm.

In FIG. 5F, an in situ second plasma enhanced treatment process 506 is performed in the deposition chamber (e.g., loop treat at 206 in FIG. 2) to treat the second oxide of the oxide layer 126. The second plasma enhanced treatment process 506 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fourth RF power level (e.g., 75 to 550 W, such as approximately 225 W) that is greater than the first and second power levels and at a fourth chamber pressure (e.g., 2 to 11 Torr, such as approximately 3 Torr). In one example, the second plasma enhanced treatment process 506 includes substantially no flow of the silicon precursor.

The process continues in FIGS. 5G-5J with further iterations of the loop deposition and loop treatments at 205 and 206 of FIG. 2 to achieve a desired final thickness of the oxide layer 126. FIG. 5G shows one example, in which a third plasma enhanced deposition process 507 is performed in the deposition chamber (e.g., 205 in FIG. 2) that deposits a third oxide on the second oxide and increases the oxide layer 126 to a third thickness T3. The oxide layer 126 after the third plasma enhanced deposition process 507 has good conformality where the third thickness T3 is uniform along the top surfaces of the polysilicon gate structure 120 and on the top surface of the semiconductor substrate 102, and the oxide layer 126 has approximately the same lateral thickness T3 along the nitride layer 124 (e.g., conformality of approximately 95 percent or more). In one example, the third plasma enhanced deposition process 507 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the third plasma enhanced deposition process 507 is approximately 0.5 or less. In the above or another example, the ratio of the flow rate of the silicon precursor (e.g., SiH₄) to the flow rate of the oxygen precursor (e.g., N₂O) in the third plasma enhanced deposition process 507 is approximately 0.0002 or more. In the above or another example, the ratio of the flow rate of the silicon precursor (e.g., SiH₄) to the flow rate of the oxygen precursor (e.g., N₂O) in the third plasma enhanced deposition process 507 is approximately 0.0025. In the above or another example, the flow rate of the silicon precursor (e.g., SiH₄) in the third plasma enhanced deposition process 507 is approximately 2 sccm or more and approximately 50 sccm or less, such as approximately 25 sccm.

In FIG. 5H, an in situ third plasma enhanced treatment process 508 is performed (e.g., loop treatment or loop treat at 206 in FIG. 2) to treat the third oxide of the oxide layer 126. The third plasma enhanced treatment process 508 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fifth RF power level (e.g., 75 to 550 W, such as approximately 225 W) that is greater than the first and second power levels and at a fourth chamber pressure (e.g., 2 to 11 Torr, such as approximately 3 Torr). In one example, the third plasma enhanced treatment process 508 includes substantially no flow of the silicon precursor.

In one example, additional loop deposition and loop treatment iterations are undertaken (not shown) and a final iteration is shown in FIGS. 5I and 5J. FIG. 5I shows one example, in which a fourth plasma enhanced deposition process 509 is performed (e.g., 205 in FIG. 2) in the deposition chamber that deposits a final oxide to increases the oxide layer 126 to a desired final thickness TF. The oxide layer 126 after the final plasma enhanced deposition process 509 has good conformality where the thickness TF is uniform along the top surfaces of the polysilicon gate structure 120 and on the top surface of the semiconductor substrate 102, and the oxide layer 126 has approximately the same lateral thickness TF along the sidewalls of the nitride layer 124 (e.g., conformality of approximately 95 percent or more). In one example, the final plasma enhanced deposition process 509 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fifth RF power level (e.g., 75 to 550 W, such as approximately 100 W) that is less than the third power level and at a fifth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the final plasma enhanced deposition process 509 is approximately 0.5 or less. In the above or another example, the ratio of the flow rate of the silicon precursor (e.g., SiH₄) to the flow rate of the oxygen precursor (e.g., N₂O) in the final plasma enhanced deposition process 509 is approximately 0.0002 or more. In the above or another example, the ratio of the flow rate of the silicon precursor (e.g., SiH₄) to the flow rate of the oxygen precursor (e.g., N₂O) in the final plasma enhanced deposition process 509 is approximately 0.0025. In the above or another example, the flow rate of the silicon precursor (e.g., SiH₄) in the final plasma enhanced deposition process 509 is approximately 2 sccm or more and approximately 50 sccm or less, such as approximately 25 sccm.

In FIG. 5J, an in situ final plasma enhanced treatment process 510 is performed (e.g., final loop treatment or loop treat at 206 in FIG. 2) in the deposition chamber to treat the final oxide of the oxide layer 126. The final plasma enhanced treatment process 510 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a sixth RF power level (e.g., 75 to 550 W, such as approximately 225 W) that is greater than the first and second power levels and at a sixth chamber pressure (e.g., 2 to 11 Torr, such as approximately 3 Torr). In one example, the final plasma enhanced treatment process 510 includes substantially no flow of the silicon precursor. In the illustrated implementation, the loop iterations provide the desired final oxide layer thickness TF and no further iterations are needed (NO at 208 in FIG. 2).

In FIG. 5K, a pumping process 511 is performed in the deposition chamber (e.g., 210 in FIG. 2) that shuts off the various gas flows and pumps the chamber to remove any process remnants and prepares the wafer or wafers for removal from the deposition chamber. Thereafter, further fabrication processing steps are performed to produce the above described packaged electronic device 100. FIG. 6 shows one example, in which an etch process 600 is performed that etches the oxide layer 126 to leave an etched oxide cap layer 126 along the sides of the gate structure of the transistor 101.

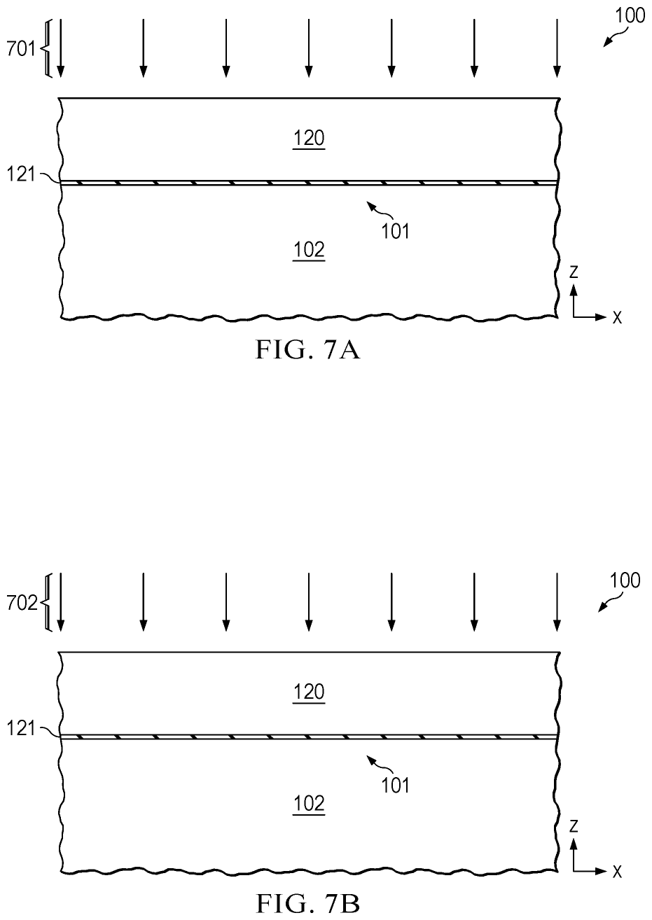

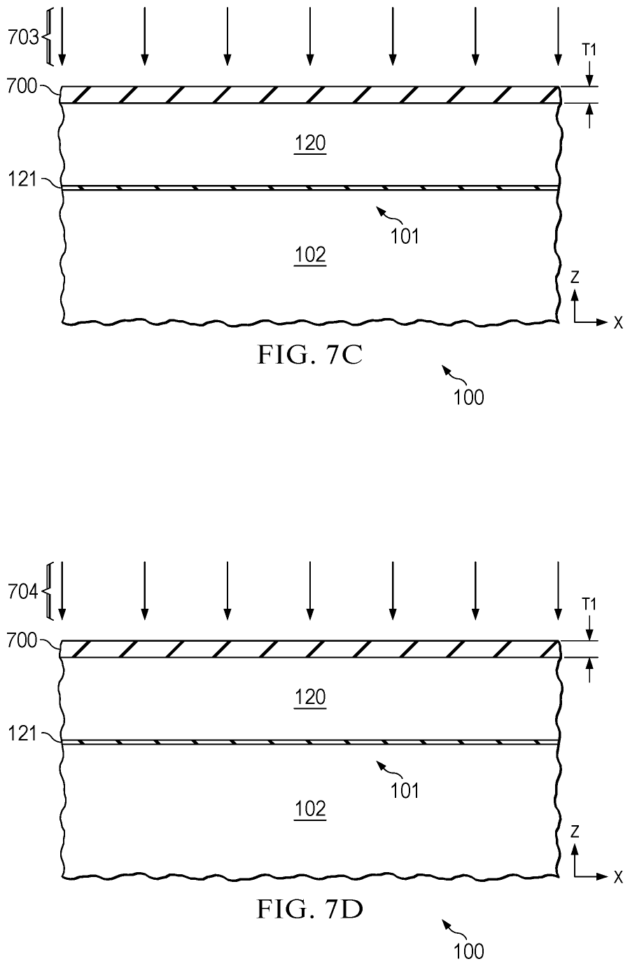

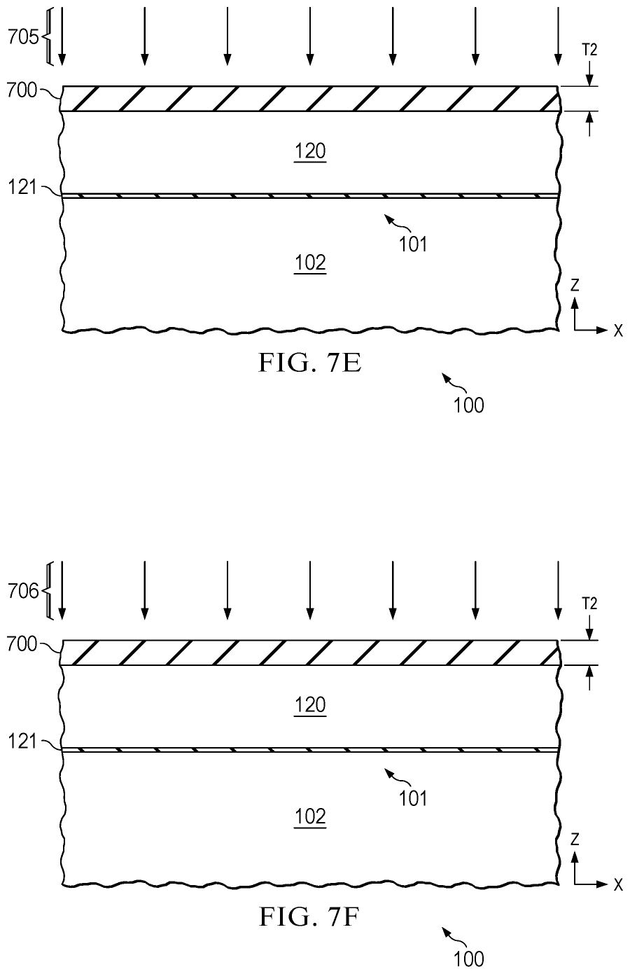

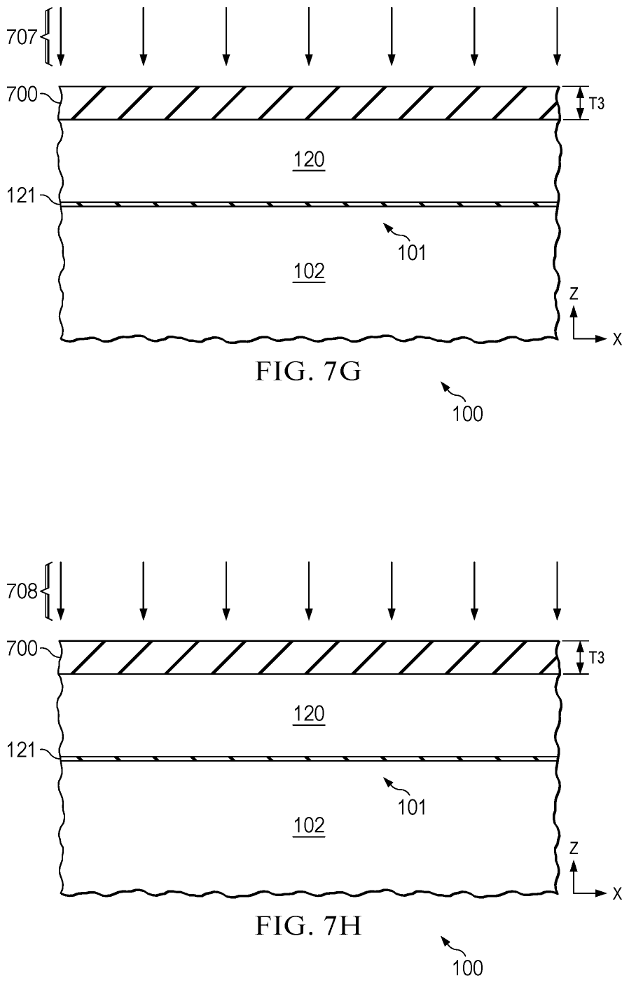

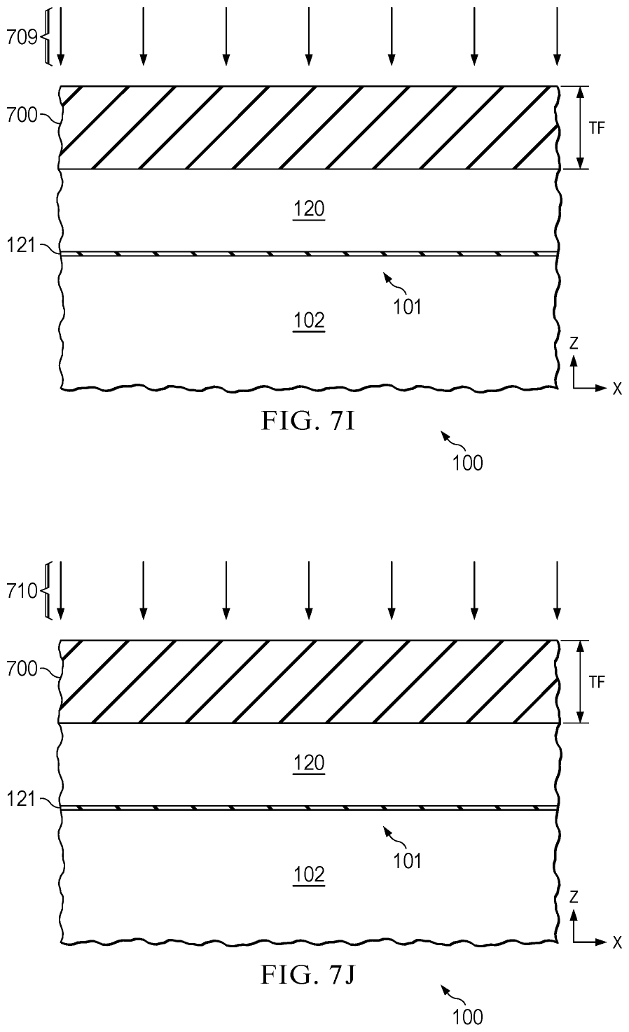

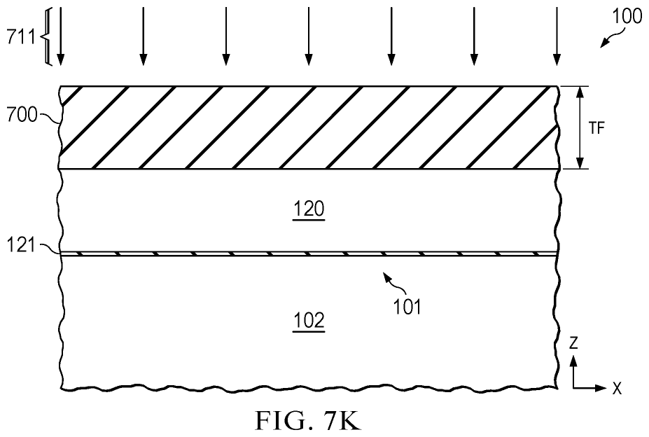

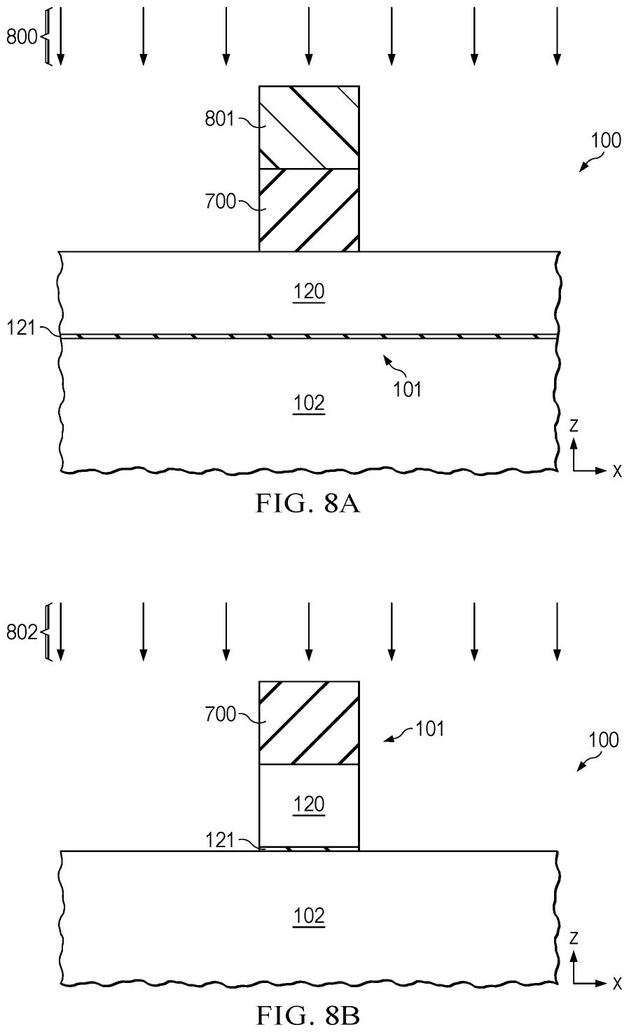

FIGS. 7A-8B show another example implementation of the method 200 in forming a sacrificial etch hard mask oxide layer 700 (FIGS. 7A-7K) and use of the hard mask 700 in patterning the polysilicon gate structure 120 of the transistor 101 (FIGS. 8A and 8B). In the example of FIGS. 7A-7K, the processed wafer has undergone formation of the gate oxide layer 121 on the surface of the semiconductor substrate 102, and a polysilicon layer 120 has been formed (e.g., by blanket deposition) on the gate oxide layer 121 as shown in FIG. 7A. The method 200 is performed in this example to form an etch mask or hard mask oxide layer 700 on the exposed surface of the polysilicon gate structure 120 by PECVD with in situ treatment and one or more iterations of loop deposition and loop treatment steps. In one example, the desired hard mask oxide layer 700 is a relatively thick oxide layer (e.g., SiₓO_{y}) of any suitable stoichiometry (e.g., where y is approximately 2×) formed by a main deposition to a first thickness T1 (e.g., approximately 100 angstroms), followed by a post treatment and a larger number (e.g., more than 5) of iterations of the loop depositions and loop treatments that add additional incremental amounts (e.g., approximately 30 angstroms or more and approximately 80 angstroms or less) to increase the thickness of the hard mask oxide layer 700 to a desired final thickness (e.g., approximately 200 angstroms or more and approximately 700 angstroms or less). The method 200 in this example is implemented as a continuous in situ process in a single environmentally controlled deposition chamber of a PECVD tool (not shown) that can accommodate one or more concurrently processed wafers, with controlled phases or stages and adjustment of process gas flows and controlled chamber temperature and pressure. The wafer or wafers are installed in the deposition chamber with the gate oxide layer 121 and the polysilicon layer 120 formed, and the chamber is sealed, and chamber pressure and chamber temperature are allowed to stabilize at 201. FIG. 7A shows one example, in which a wafer is installed in the deposition chamber and a stabilization process 701 is performed (e.g., 201 in FIG. 2 above) to stabilize the environmental conditions inside the chamber.

In FIG. 7B a plasma enhanced pretreatment process 702 is performed in the deposition chamber (e.g., 202 in FIG. 2) to pretreat the surface of the polysilicon layer 120 on which the hard mask oxide layer 700 is to be formed. The plasma enhanced pretreatment process 702 in some examples uses low RF power to protect the surface and facilitate adhesion of the new oxide film to the existing surface of a previous layer or substrate. The pretreatment process 702 also preheats the surface with plasma and inert gas to facilitate outgassing and introduces some oxygen to facilitate adhesion of the subsequently deposited oxide layer. In one implementation, the plasma enhanced pretreatment process 702 includes concurrent flows of an inert gas (e.g., helium (He), argon (Ar), etc.) at a non-zero flow rate (e.g., 700 to 25,000 standard cubic centimeters per minute (sccm or cm³/m) such as approximately 1,000 sccm) and an oxygen precursor (e.g., nitrous oxide (N₂O)) at a non-zero flow rate (e.g., 500 to 15,000 sccm, such as approximately 4,000 sccm) at a first radio frequency (RF) power level (e.g., 75 to 550 W, such as approximately 120 W) and a first chamber pressure (e.g., 2 to 11 Torr, such as approximately 3 Torr) and a first chamber temperature (e.g., 150 to 550 degrees C., such as approximately 350 degrees C.). In the above or other examples, the plasma enhanced pretreatment process 702 includes substantially no flow of silicon precursor.

In FIG. 7C, a first plasma enhanced deposition process 703 is performed in the deposition chamber (e.g., a main deposition phase at 203 in FIG. 2). The first plasma enhanced deposition process 703 deposits a first oxide of the oxide layer 700 to a first thickness T1 (e.g., approximately 100 angstroms or more) on the exposed surface of the polysilicon gate structure 120. The first plasma enhanced deposition in the illustrated example has a low deposition rate to facilitate high film quality with little or no contaminants in the film material. In addition, the resulting deposited oxide layer 700 has good conformality, where the first thickness T1 in FIG. 7C is uniform along the top surface of the polysilicon gate structure 120. In one example, the first plasma enhanced deposition process 703 is a PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a second RF power level (e.g., 75 to 550 W, such as approximately 100 W) and a second chamber pressure (e.g., 2 to 11 Torr, such as approximately 3 Torr). In one example, the second chamber pressure is greater than the first chamber pressure. In this or another example, a ratio of the flow rate of the silicon precursor (e.g., SiH₄) to a flow rate of the oxygen precursor (e.g., N₂O) in the first plasma enhanced deposition process 703 is approximately 0.5 or less. In the above or another example, the ratio of the flow rate of the silicon precursor (e.g., SiH₄) to the flow rate of the oxygen precursor (e.g., N₂O) in the first plasma enhanced deposition process 703 is approximately 0.0002 or more. In the above or another example, the ratio of the flow rate of the silicon precursor (e.g., SiH₄) to the flow rate of the oxygen precursor (e.g., N₂O) in the first plasma enhanced deposition process 703 is approximately 0.0025. In the above or another example, the flow rate of the silicon precursor (e.g., SiH₄) in the first plasma enhanced deposition process 703 is approximately 2 sccm or more and approximately 50 sccm or less, such as approximately 25 sccm.

In FIG. 7D, an in situ first plasma enhanced treatment process 704 is performed in the deposition chamber (e.g., a post treatment or post-treat phase at 204 in FIG. 2) to treat the first oxide of the oxide layer 700. In one example, the first plasma enhanced treatment process 704 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a third RF power level (e.g., 75 to 550 W, such as approximately 225 W) that is greater than the first and second power levels and at a third chamber pressure (e.g., 2 to 11 Torr, such as approximately 3 Torr). In one example, the first plasma enhanced treatment process 704 includes substantially no flow of the silicon precursor.

In FIG. 7E, a second plasma enhanced deposition process 705 is performed in the deposition chamber (e.g., a loop deposition at 205 in FIG. 2) to deposit a second oxide on the first oxide and increase the oxide layer 700 to a second thickness T2. The oxide layer 700 after the second plasma enhanced deposition process 705 has good conformality and the second thickness T2 is uniform along the top surfaces of the polysilicon gate structure 120. In one example, the second plasma enhanced deposition process 705 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the second plasma enhanced deposition process 705 is approximately 0.5 or less. In the above or another example, the ratio of the flow rate of the silicon precursor (e.g., SiH₄) to the flow rate of the oxygen precursor (e.g., N₂O) in the second plasma enhanced deposition process 705 is approximately 0.0002 or more. In the above or another example, the ratio of the flow rate of the silicon precursor (e.g., SiH₄) to the flow rate of the oxygen precursor (e.g., N₂O) in the second plasma enhanced deposition process 705 is approximately 0.0025. In the above or another example, the flow rate of the silicon precursor (e.g., SiH₄) in the second plasma enhanced deposition process 705 is approximately 2 sccm or more and approximately 50 sccm or less, such as approximately 25 sccm.

In FIG. 7F, an in situ second plasma enhanced treatment process 706 is performed in the deposition chamber (e.g., loop treat at 206 in FIG. 2) to treat the second oxide of the oxide layer 700. The second plasma enhanced treatment process 706 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fourth RF power level (e.g., 75 to 550 W, such as approximately 225 W) that is greater than the first and second power levels and at a fourth chamber pressure (e.g., 2 to 11 Torr, such as approximately 3 Torr). In one example, the second plasma enhanced treatment process 706 includes substantially no flow of the silicon precursor.

The process continues in FIGS. 7G-7J with further iterations of the loop deposition and loop treatments at 205 and 206 of FIG. 2 to achieve a desired final thickness of the oxide layer 700. FIG. 7G shows one example, in which a third plasma enhanced deposition process 707 is performed in the deposition chamber (e.g., 205 in FIG. 2) that deposits a third oxide on the second oxide and increases the oxide layer 700 to a third thickness T3. The oxide layer 700 after the third plasma enhanced deposition process 707 has good conformality and the third thickness T3 is uniform along the top surface of the polysilicon gate structure 120. In one example, the third plasma enhanced deposition process 707 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the third plasma enhanced deposition process 707 is approximately 0.5 or less. In the above or another example, the ratio of the flow rate of the silicon precursor (e.g., SiH₄) to the flow rate of the oxygen precursor (e.g., N₂O) in the third plasma enhanced deposition process 707 is approximately 0.0002 or more. In the above or another example, the ratio of the flow rate of the silicon precursor (e.g., SiH₄) to the flow rate of the oxygen precursor (e.g., N₂O) in the third plasma enhanced deposition process 707 is approximately 0.0025. In the above or another example, the flow rate of the silicon precursor (e.g., SiH₄) in the third plasma enhanced deposition process 707 is approximately 2 sccm or more and approximately 50 sccm or less, such as approximately 25 sccm.

In FIG. 7H, an in situ third plasma enhanced treatment process 708 is performed (e.g., loop treatment or loop treat at 206 in FIG. 2) to treat the third oxide of the oxide layer 700. The third plasma enhanced treatment process 708 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fifth RF power level (e.g., 75 to 550 W, such as approximately 225 W) that is greater than the first and second power levels and at a fourth chamber pressure (e.g., 2 to 11 Torr, such as approximately 3 Torr). In one example, the third plasma enhanced treatment process 708 includes substantially no flow of the silicon precursor.

In one example, additional loop deposition and loop treatment iterations are undertaken (not shown) and a final iteration is shown in FIGS. 71 and 7J. FIG. 7I shows one example, in which a fourth plasma enhanced deposition process 709 is performed (e.g., 205 in FIG. 2) in the deposition chamber that deposits a final oxide to increases the oxide layer 700 to a desired final thickness TF. The oxide layer 700 after the final plasma enhanced deposition process 709 has good uniformity where the thickness TF is uniform along the top surface of the polysilicon gate structure 120. In one example, the final plasma enhanced deposition process 709 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fifth RF power level (e.g., 75 to 550 W, such as approximately 100 W) that is less than the third power level and at a fifth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the final plasma enhanced deposition process 709 is approximately 0.5 or less. In the above or another example, the ratio of the flow rate of the silicon precursor (e.g., SiH₄) to the flow rate of the oxygen precursor (e.g., N₂O) in the final plasma enhanced deposition process 709 is approximately 0.0002 or more. In the above or another example, the ratio of the flow rate of the silicon precursor (e.g., SiH₄) to the flow rate of the oxygen precursor (e.g., N₂O) in the final plasma enhanced deposition process 709 is approximately 0.0025. In the above or another example, the flow rate of the silicon precursor (e.g., SiH₄) in the final plasma enhanced deposition process 709 is approximately 2 sccm or more and approximately 50 sccm or less, such as approximately 25 sccm.

In FIG. 7J, an in situ final plasma enhanced treatment process 710 is performed (e.g., final loop treatment or loop treat at 206 in FIG. 2) in the deposition chamber to treat the final oxide of the oxide layer 700. The final plasma enhanced treatment process 710 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a sixth RF power level (e.g., 75 to 550 W, such as approximately 225 W) that is greater than the first and second power levels and at a sixth chamber pressure (e.g., 2 to 11 Torr, such as approximately 3 Torr). In one example, the final plasma enhanced treatment process 710 includes substantially no flow of the silicon precursor. In the illustrated implementation, the loop iterations provide the desired final oxide layer thickness TF and no further iterations are needed (NO at 208 in FIG. 2).

In FIG. 7K, a pumping process 711 is performed in the deposition chamber (e.g., 210 in FIG. 2) that shuts off the various gas flows and pumps the chamber to remove any process remnants and prepares the wafer or wafers for removal from the deposition chamber. Thereafter, further fabrication processing steps are performed to produce the above described packaged electronic device 100. FIGS. 8A and 8B show one example, in which a hard mask patterning process 800 (e.g., an etch process) is performed using a patterned resist 801 in FIG. 8A to pattern the hard mask oxide layer 700 over a prospective transistor gate portion of the polysilicon layer 120, and a gate etch process 802 is performed in FIG. 8B that etches the exposed portions of the polysilicon layer 120 and the gate oxide layer 121 to define the patterned polysilicon gate of the transistor 101.

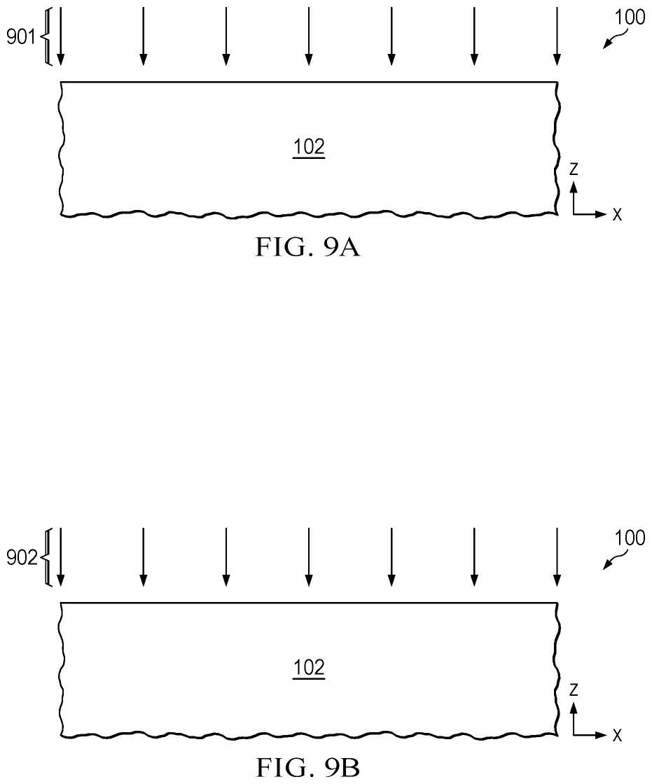

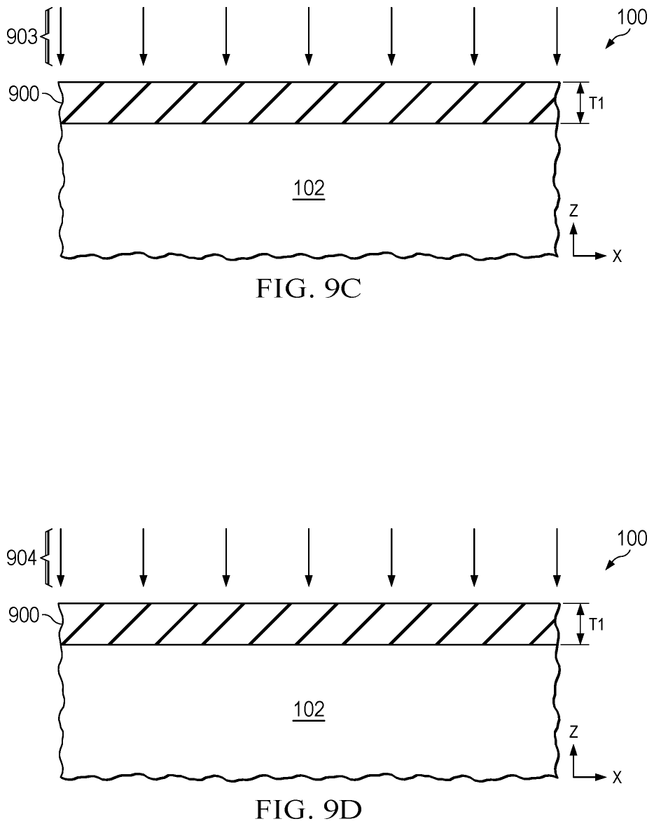

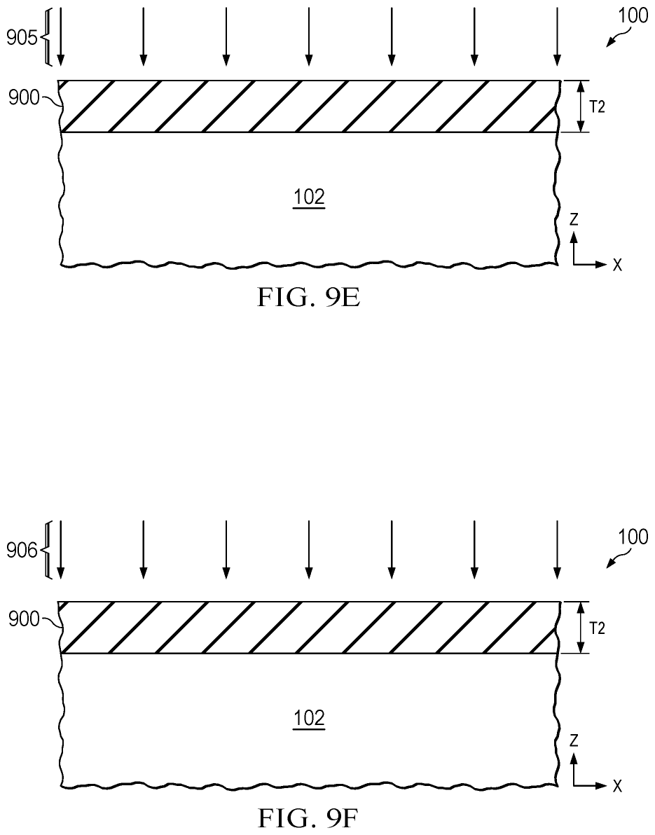

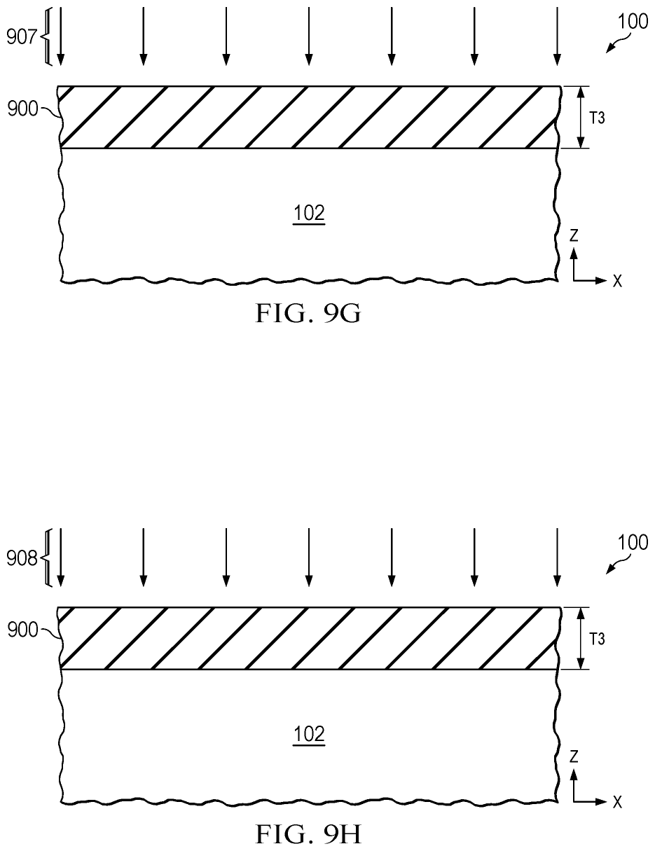

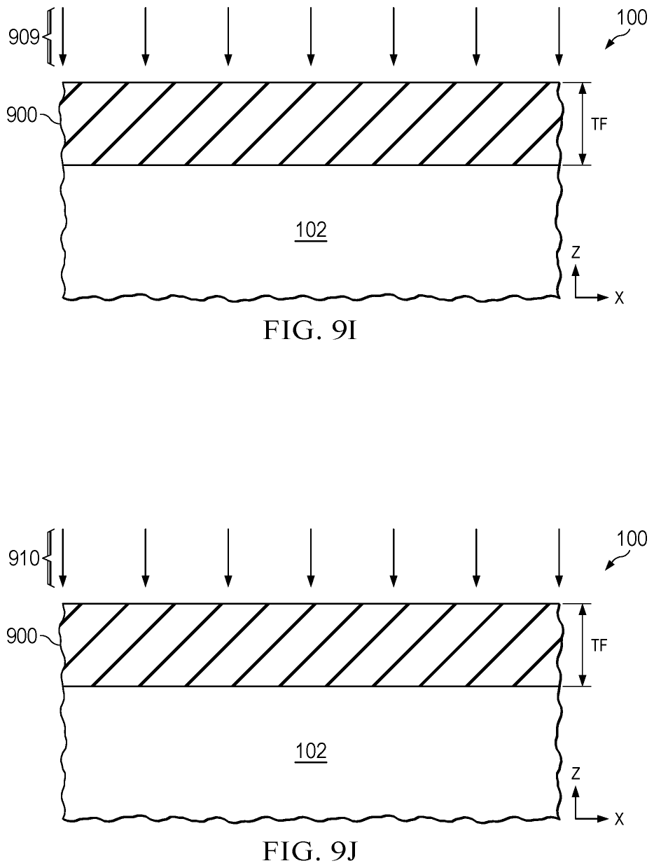

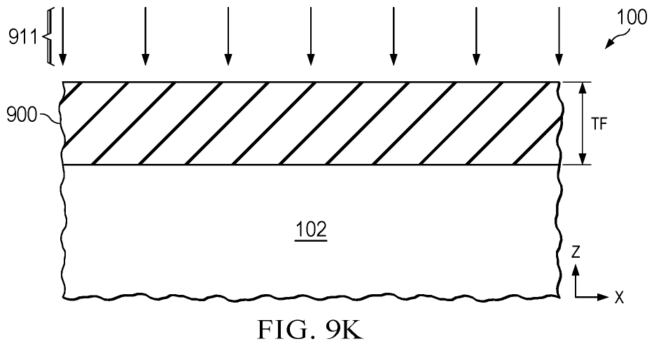

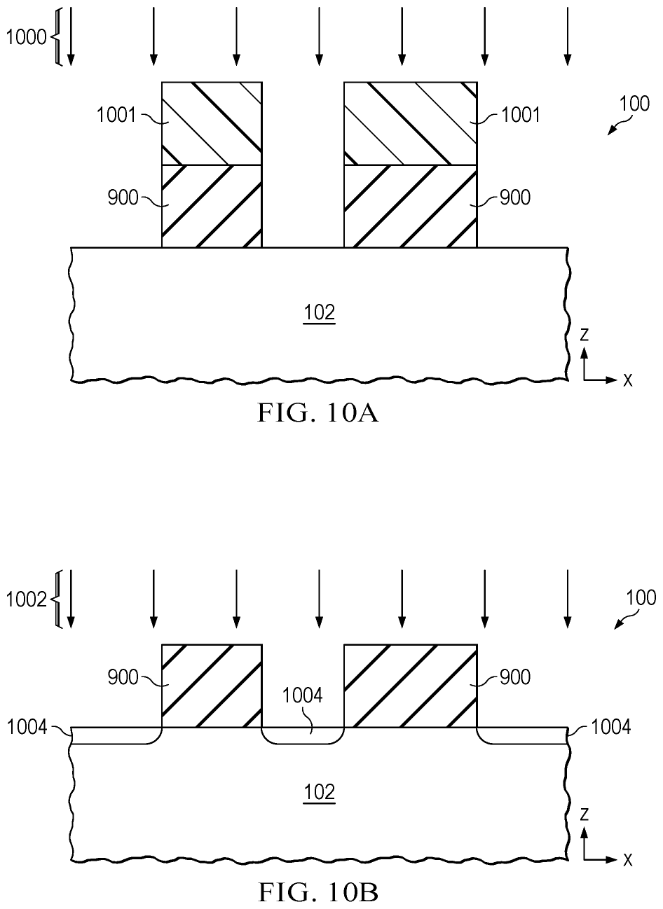

FIGS. 9A-10B show another example implementation of the method 200 in forming a sacrificial trench etch hard mask oxide layer 900 (FIGS. 9A-9K) and using the oxide layer 900 to etch trenches for shallow trench isolation (STI) structures of the electronic device 100. The method 200 is performed in this example to form an etch mask or hard mask oxide layer 900 on the exposed surface of the semiconductor substrate 102 by PECVD with in situ treatment and one or more iterations of loop deposition and loop treatment steps. In one example, the desired hard mask oxide layer 900 is a relatively thick oxide layer (e.g., SiₓO_{y}) of any suitable stoichiometry (e.g., where y is approximately 2×) formed by a main deposition to a first thickness T1 (e.g., approximately 100 angstroms), followed by a post treatment and a larger number (e.g., more than 5) of iterations of the loop depositions and loop treatments that add additional incremental amounts (e.g., approximately 30 angstroms or more and approximately 80 angstroms or less) to increase the thickness of the hard mask oxide layer 900 to a desired final thickness (e.g., approximately 200 angstroms or more and approximately 900 angstroms or less). The method 200 in this example is implemented as a continuous in situ process in a single environmentally controlled deposition chamber of a PECVD tool (not shown) that can accommodate one or more concurrently processed wafers, with controlled phases or stages and adjustment of process gas flows and controlled chamber temperature and pressure. The wafer or wafers are installed in the deposition chamber and the chamber is sealed and chamber pressure and chamber temperature are allowed to stabilize at 201. FIG. 9A shows one example, in which a wafer is installed in the deposition chamber and a stabilization process 901 is performed (e.g., 201 in FIG. 2 above) to stabilize the environmental conditions inside the chamber.

In FIG. 9B a plasma enhanced pretreatment process 902 is performed in the deposition chamber (e.g., 202 in FIG. 2) to pretreat the surface of the semiconductor substrate 102 on which the hard mask oxide layer 900 is to be formed. The plasma enhanced pretreatment process 902 in some examples uses low RF power to protect the surface and facilitate adhesion of the new oxide film to the existing surface of the substrate 102. The pretreatment process 902 also preheats the surface with plasma and inert gas to facilitate outgassing and introduces some oxygen to facilitate adhesion of the subsequently deposited oxide layer. In one implementation, the plasma enhanced pretreatment process 902 includes concurrent flows of an inert gas (e.g., helium (He), argon (Ar), etc.) at a non-zero flow rate (e.g., 700 to 25,000 standard cubic centimeters per minute (sccm or cm³/m) such as approximately 1,000 sccm) and an oxygen precursor (e.g., nitrous oxide (N₂O)) at a non-zero flow rate (e.g., 500 to 15,000 sccm, such as approximately 4,000 sccm) at a first radio frequency (RF) power level (e.g., 75 to 550 W, such as approximately 120 W) and a first chamber pressure (e.g., 2 to 11 Torr, such as approximately 3 Torr) and a first chamber temperature (e.g., 150 to 550 degrees C., such as approximately 350 degrees C.). In the above or other examples, the plasma enhanced pretreatment process 902 includes substantially no flow of silicon precursor.

In FIG. 9C, a first plasma enhanced deposition process 903 is performed in the deposition chamber (e.g., a main deposition phase at 203 in FIG. 2). The first plasma enhanced deposition process 903 deposits a first oxide of the oxide layer 900 to a first thickness T1 (e.g., approximately 100 angstroms or more) on the exposed surface of the semiconductor substrate 102. The first plasma enhanced deposition in the illustrated example has a low deposition rate to facilitate high film quality with little or no contaminants in the film material. In addition, the resulting deposited oxide layer 900 has good conformality, where the first thickness T1 in FIG. 9C is uniform along the top surface of the semiconductor substrate 102. In one example, the first plasma enhanced deposition process 903 is a PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a second RF power level (e.g., 75 to 550 W, such as approximately 100 W) and a second chamber pressure (e.g., 2 to 11 Torr, such as approximately 3 Torr). In one example, the second chamber pressure is greater than the first chamber pressure. In this or another example, a ratio of the flow rate of the silicon precursor (e.g., SiH₄) to a flow rate of the oxygen precursor (e.g., N₂O) in the first plasma enhanced deposition process 903 is approximately 0.5 or less. In the above or another example, the ratio of the flow rate of the silicon precursor (e.g., SiH₄) to the flow rate of the oxygen precursor (e.g., N₂O) in the first plasma enhanced deposition process 903 is approximately 0.0002 or more.

In the above or another example, the ratio of the flow rate of the silicon precursor (e.g., SiH₄) to the flow rate of the oxygen precursor (e.g., N₂O) in the first plasma enhanced deposition process 903 is approximately 0.0025. In the above or another example, the flow rate of the silicon precursor (e.g., SiH₄) in the first plasma enhanced deposition process 903 is approximately 2 sccm or more and approximately 50 sccm or less, such as approximately 25 sccm.

In FIG. 9D, an in situ first plasma enhanced treatment process 904 is performed in the deposition chamber (e.g., a post treatment or post-treat phase at 204 in FIG. 2) to treat the first oxide of the oxide layer 900. In one example, the first plasma enhanced treatment process 904 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a third RF power level (e.g., 75 to 550 W, such as approximately 225 W) that is greater than the first and second power levels and at a third chamber pressure (e.g., 2 to 11 Torr, such as approximately 3 Torr). In one example, the first plasma enhanced treatment process 904 includes substantially no flow of the silicon precursor.

In FIG. 9E, a second plasma enhanced deposition process 905 is performed in the deposition chamber (e.g., a loop deposition at 205 in FIG. 2) to deposit a second oxide on the first oxide and increase the oxide layer 900 to a second thickness T2. The oxide layer 900 after the second plasma enhanced deposition process 905 has good conformality and the second thickness T2 is uniform along the top surfaces of the semiconductor substrate 102. In one example, the second plasma enhanced deposition process 905 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the second plasma enhanced deposition process 905 is approximately 0.5 or less. In the above or another example, the ratio of the flow rate of the silicon precursor (e.g., SiH₄) to the flow rate of the oxygen precursor (e.g., N₂O) in the second plasma enhanced deposition process 905 is approximately 0.0002 or more. In the above or another example, the ratio of the flow rate of the silicon precursor (e.g., SiH₄) to the flow rate of the oxygen precursor (e.g., N₂O) in the second plasma enhanced deposition process 905 is approximately 0.0025. In the above or another example, the flow rate of the silicon precursor (e.g., SiH₄) in the second plasma enhanced deposition process 905 is approximately 2 sccm or more and approximately 50 sccm or less, such as approximately 25 sccm.

In FIG. 9F, an in situ second plasma enhanced treatment process 906 is performed in the deposition chamber (e.g., loop treat at 206 in FIG. 2) to treat the second oxide of the oxide layer 900. The second plasma enhanced treatment process 906 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fourth RF power level (e.g., 75 to 550 W, such as approximately 225 W) that is greater than the first and second power levels and at a fourth chamber pressure (e.g., 2 to 11 Torr, such as approximately 3 Torr). In one example, the second plasma enhanced treatment process 906 includes substantially no flow of the silicon precursor.

The process continues in FIGS. 9G-9J with further iterations of the loop deposition and loop treatments at 205 and 206 of FIG. 2 to achieve a desired final thickness of the oxide layer 900. FIG. 9G shows one example, in which a third plasma enhanced deposition process 907 is performed in the deposition chamber (e.g., 205 in FIG. 2) that deposits a third oxide on the second oxide and increases the oxide layer 900 to a third thickness T3. The oxide layer 900 after the third plasma enhanced deposition process 907 has good conformality and the third thickness T3 is uniform along the top surface of the semiconductor substrate 102. In one example, the third plasma enhanced deposition process 907 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the third plasma enhanced deposition process 907 is approximately 0.5 or less. In the above or another example, the ratio of the flow rate of the silicon precursor (e.g., SiH₄) to the flow rate of the oxygen precursor (e.g., N₂O) in the third plasma enhanced deposition process 907 is approximately 0.0002 or more. In the above or another example, the ratio of the flow rate of the silicon precursor (e.g., SiH₄) to the flow rate of the oxygen precursor (e.g., N₂O) in the third plasma enhanced deposition process 907 is approximately 0.0025. In the above or another example, the flow rate of the silicon precursor (e.g., SiH₄) in the third plasma enhanced deposition process 907 is approximately 2 sccm or more and approximately 50 sccm or less, such as approximately 25 sccm.

In FIG. 9H, an in situ third plasma enhanced treatment process 908 is performed (e.g., loop treatment or loop treat at 206 in FIG. 2) to treat the third oxide of the oxide layer 900. The third plasma enhanced treatment process 908 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fifth RF power level (e.g., 75 to 550 W, such as approximately 225 W) that is greater than the first and second power levels and at a fourth chamber pressure (e.g., 2 to 11 Torr, such as approximately 3 Torr). In one example, the third plasma enhanced treatment process 908 includes substantially no flow of the silicon precursor.

In one example, additional loop deposition and loop treatment iterations are undertaken (not shown) and a final iteration is shown in FIGS. 9I and 9J. FIG. 9I shows one example, in which a fourth plasma enhanced deposition process 909 is performed (e.g., 205 in FIG. 2) in the deposition chamber that deposits a final oxide to increases the oxide layer 900 to a desired final thickness TF. The oxide layer 900 after the final plasma enhanced deposition process 909 has good uniformity where the thickness TF is uniform along the top surface of the semiconductor substrate 102. In one example, the final plasma enhanced deposition process 909 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fifth RF power level (e.g., 75 to 550 W, such as approximately 100 W) that is less than the third power level and at a fifth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the final plasma enhanced deposition process 909 is approximately 0.5 or less. In the above or another example, the ratio of the flow rate of the silicon precursor (e.g., SiH₄) to the flow rate of the oxygen precursor (e.g., N₂O) in the final plasma enhanced deposition process 909 is approximately 0.0002 or more. In the above or another example, the ratio of the flow rate of the silicon precursor (e.g., SiH₄) to the flow rate of the oxygen precursor (e.g., N₂O) in the final plasma enhanced deposition process 909 is approximately 0.0025. In the above or another example, the flow rate of the silicon precursor (e.g., SiH₄) in the final plasma enhanced deposition process 909 is approximately 2 sccm or more and approximately 50 sccm or less, such as approximately 25 sccm.

In FIG. 9J, an in situ final plasma enhanced treatment process 910 is performed (e.g., final loop treatment or loop treat at 206 in FIG. 2) in the deposition chamber to treat the final oxide of the oxide layer 900. The final plasma enhanced treatment process 910 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a sixth RF power level (e.g., 75 to 550 W, such as approximately 225 W) that is greater than the first and second power levels and at a sixth chamber pressure (e.g., 2 to 11 Torr, such as approximately 3 Torr). In one example, the final plasma enhanced treatment process 910 includes substantially no flow of the silicon precursor. In the illustrated implementation, the loop iterations provide the desired final oxide layer thickness TF and no further iterations are needed (NO at 208 in FIG. 2).

In FIG. 9K, a pumping process 911 is performed in the deposition chamber (e.g., 210 in FIG. 2) that shuts off the various gas flows and pumps the chamber to remove any process remnants and prepares the wafer or wafers for removal from the deposition chamber. Thereafter, further fabrication processing steps are performed to produce the above described packaged electronic device 100. FIGS. 10A and 10B show one example, in which a hard mask patterning process 1000 (e.g., an etch process) is performed using a patterned resist 1001 in FIG. 10A to pattern the hard mask oxide layer 900 to expose prospective STI trench regions of the semiconductor substrate 102. A trench etch process 1002 is performed in FIG. 10B that etches the exposed portions of the semiconductor substrate 102 to define STI trenches 1004.

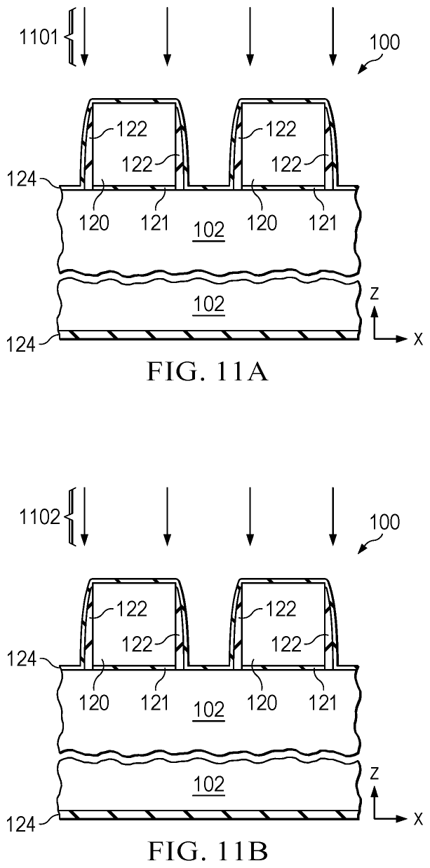

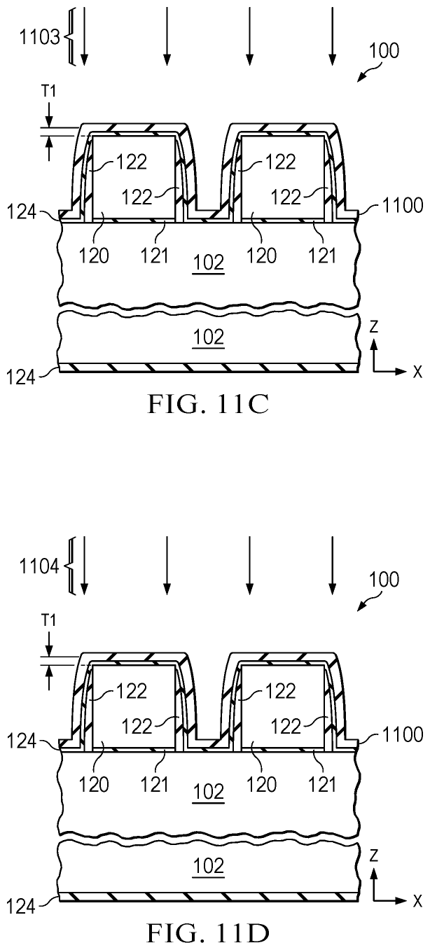

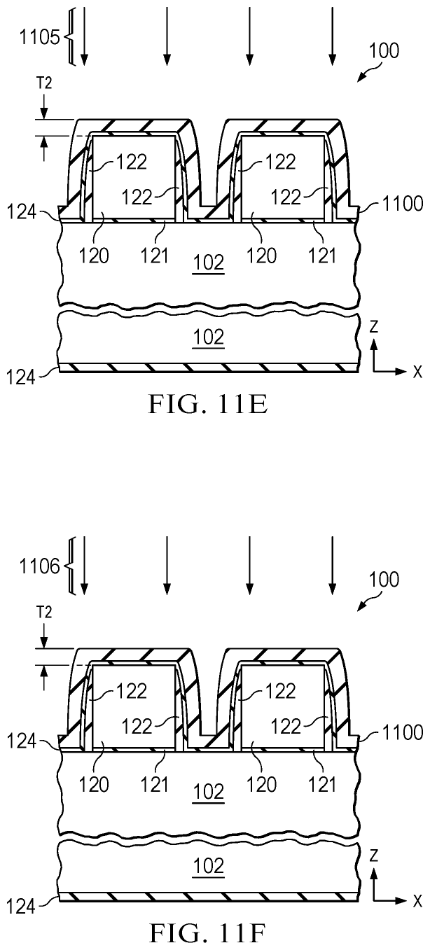

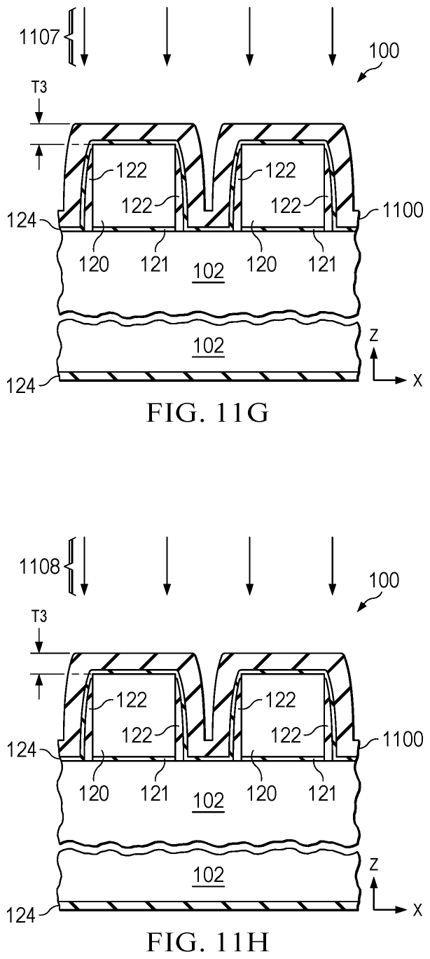

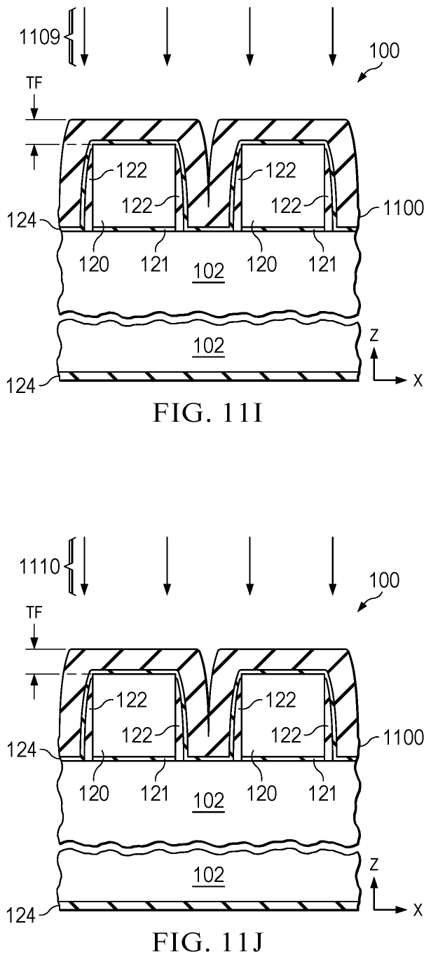

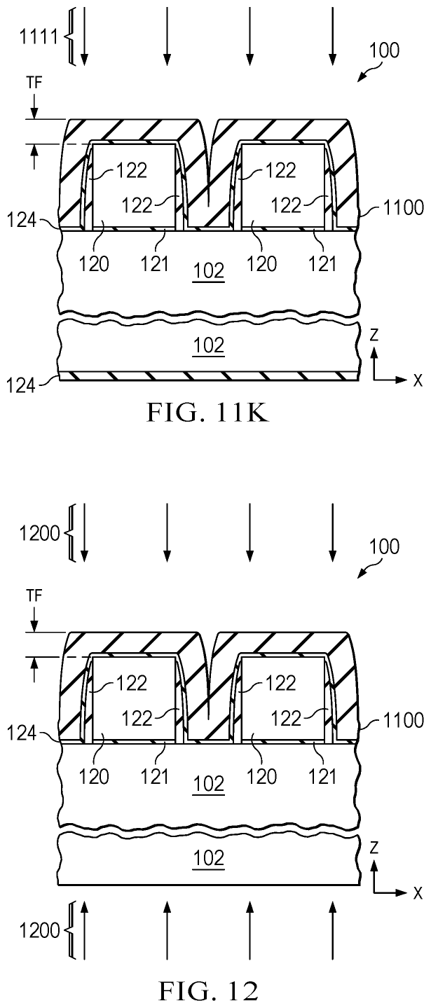

FIGS. 11A-12 show another example implementation of the method 200 in forming a sacrificial protection oxide layer 1100 (FIGS. 11A-11K) and using the oxide layer 1100 to protect front side features during wafer back side etching (FIG. 12) during fabrication of the electronic device 100. The method 200 is performed in this example to form a front side protection oxide layer 1100 on the front side of the wafer, for example, over a deposited nitride layer 124, by PECVD with in situ treatment and one or more iterations of loop deposition and loop treatment steps. The processed wafer is shown in FIG. 11A after deposition of the nitride layer 124 on the spacer oxide layer 122 of the polysilicon structures, in which the nitride deposition also deposits the nitride 124 on the back side (e.g., bottom) of the processed wafer. The protection oxide layer 1100 is formed on the wafer front side to protect the front side features while etching the nitride layer 124 of the wafer back side.

In one example, the desired protection oxide layer 1100 is a relatively thick oxide layer (e.g., SiₓO_{y}) of any suitable stoichiometry (e.g., where y is approximately 2×) formed by a main deposition to a first thickness T1 (e.g., approximately 100 angstroms), followed by a post treatment and a larger number (e.g., more than 5) of iterations of the loop depositions and loop treatments that add additional incremental amounts (e.g., approximately 30 angstroms or more and approximately 80 angstroms or less) to increase the thickness of the protection oxide layer 1100 to a desired final thickness (e.g., approximately 200 angstroms or more and approximately 1100 angstroms or less). The method 200 in this example is implemented as a continuous in situ process in a single environmentally controlled deposition chamber of a PECVD tool (not shown) that can accommodate one or more concurrently processed wafers, with controlled phases or stages and adjustment of process gas flows and controlled chamber temperature and pressure. The wafer or wafers are installed in the deposition chamber and the chamber is sealed and chamber pressure and chamber temperature are allowed to stabilize at 201. FIG. 11A shows one example, in which a wafer is installed in the deposition chamber and a stabilization process 1101 is performed (e.g., 201 in FIG. 2 above) to stabilize the environmental conditions inside the chamber.

In FIG. 11B a plasma enhanced pretreatment process 1102 is performed in the deposition chamber (e.g., 202 in FIG. 2) to pretreat the surface of the front side structures on which the protection oxide layer 1100 is to be formed. The plasma enhanced pretreatment process 1102 in some examples uses low RF power to protect the surface and facilitate adhesion of the new oxide film to the existing surface of the front side features (e.g., the front side nitride layer 124). The pretreatment process 1102 also preheats the surface with plasma and inert gas to facilitate outgassing and introduces some oxygen to facilitate adhesion of the subsequently deposited oxide layer. In one implementation, the plasma enhanced pretreatment process 1102 includes concurrent flows of an inert gas (e.g., helium (He), argon (Ar), etc.) at a non-zero flow rate (e.g., 700 to 25,000 standard cubic centimeters per minute (sccm or cm³/m) such as approximately 1,000 sccm) and an oxygen precursor (e.g., nitrous oxide (N₂O)) at a non-zero flow rate (e.g., 500 to 15,000 sccm, such as approximately 4,000 sccm) at a first radio frequency (RF) power level (e.g., 75 to 550 W, such as approximately 120 W) and a first chamber pressure (e.g., 2 to 11 Torr, such as approximately 3 Torr) and a first chamber temperature (e.g., 150 to 550 degrees C., such as approximately 350 degrees C.). In the above or other examples, the plasma enhanced pretreatment process 1102 includes substantially no flow of silicon precursor.

In FIG. 11C, a first plasma enhanced deposition process 1103 is performed in the deposition chamber (e.g., a main deposition phase at 203 in FIG. 2). The first plasma enhanced deposition process 1103 deposits a first oxide of the oxide layer 1100 to a first thickness T1 (e.g., approximately 100 angstroms or more) on the exposed surface of the nitride layer 124. The first plasma enhanced deposition in the illustrated example has a low deposition rate to facilitate high film quality with little or no contaminants in the film material. In addition, the resulting deposited oxide layer 1100 has good conformality, where the first thickness T1 in FIG. 11C is uniform along the top surfaces of the illustrated front side features, as well as along the sidewalls thereof. In one example, the first plasma enhanced deposition process 1103 is a PECVD process that includes concurrent flows of the inert gas (e.g., helium (He), argon (Ar), etc.) at a non-zero flow rate (e.g., 500 to 25,000 sccm) such as approximately 10,000 sccm, the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a second RF power level (e.g., 75 to 550 W, such as approximately 100 W) and a second chamber pressure (e.g., 2 to 11 Torr, such as approximately 3 Torr). In one example, the second chamber pressure is greater than the first chamber pressure. In this or another example, a ratio of the flow rate of the silicon precursor (e.g., SiH₄) to a flow rate of the oxygen precursor (e.g., N₂O) in the first plasma enhanced deposition process 1103 is approximately 0.5 or less. In the above or another example, the ratio of the flow rate of the silicon precursor (e.g., SiH₄) to the flow rate of the oxygen precursor (e.g., N₂O) in the first plasma enhanced deposition process 1103 is approximately 0.0002 or more. In the above or another example, the ratio of the flow rate of the silicon precursor (e.g., SiH₄) to the flow rate of the oxygen precursor (e.g., N₂O) in the first plasma enhanced deposition process 1103 is approximately 0.0025. In the above or another example, the flow rate of the silicon precursor (e.g., SiH₄) in the first plasma enhanced deposition process 1103 is approximately 2 sccm or more and approximately 50 sccm or less, such as approximately 25 sccm.

In FIG. 11D, an in situ first plasma enhanced treatment process 1104 is performed in the deposition chamber (e.g., a post treatment or post-treat phase at 204 in FIG. 2) to treat the first oxide of the oxide layer 1100. In one example, the first plasma enhanced treatment process 1104 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a third RF power level (e.g., 75 to 550 W, such as approximately 225 W) that is greater than the first and second power levels and at a third chamber pressure (e.g., 2 to 11 Torr, such as approximately 3 Torr). In one example, the first plasma enhanced treatment process 1104 includes substantially no flow of the silicon precursor.

In FIG. 11E, a second plasma enhanced deposition process 1105 is performed in the deposition chamber (e.g., a loop deposition at 205 in FIG. 2) to deposit a second oxide on the first oxide and increase the oxide layer 1100 to a second thickness T2. The oxide layer 1100 after the second plasma enhanced deposition process 1105 has good conformality, where the second thickness T2 in FIG. 11C is uniform along the top surfaces of the illustrated front side features, as well as along the sidewalls thereof. In one example, the second plasma enhanced deposition process 1105 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the second plasma enhanced deposition process 1105 is approximately 0.5 or less. In the above or another example, the ratio of the flow rate of the silicon precursor (e.g., SiH₄) to the flow rate of the oxygen precursor (e.g., N₂O) in the second plasma enhanced deposition process 1105 is approximately 0.0002 or more. In the above or another example, the ratio of the flow rate of the silicon precursor (e.g., SiH₄) to the flow rate of the oxygen precursor (e.g., N₂O) in the second plasma enhanced deposition process 1105 is approximately 0.0025. In the above or another example, the flow rate of the silicon precursor (e.g., SiH₄) in the second plasma enhanced deposition process 1105 is approximately 2 sccm or more and approximately 50 sccm or less, such as approximately 25 sccm.

In FIG. 11F, an in situ second plasma enhanced treatment process 1106 is performed in the deposition chamber (e.g., loop treat at 206 in FIG. 2) to treat the second oxide of the oxide layer 1100. The second plasma enhanced treatment process 1106 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fourth RF power level (e.g., 75 to 550 W, such as approximately 225 W) that is greater than the first and second power levels and at a fourth chamber pressure (e.g., 2 to 11 Torr, such as approximately 3 Torr). In one example, the second plasma enhanced treatment process 1106 includes substantially no flow of the silicon precursor.

The process continues in FIGS. 11G-11J with further iterations of the loop deposition and loop treatments at 205 and 206 of FIG. 2 to achieve a desired final thickness of the oxide layer 1100. FIG. 11G shows one example, in which a third plasma enhanced deposition process 1107 is performed in the deposition chamber (e.g., 205 in FIG. 2) that deposits a third oxide on the second oxide and increases the oxide layer 1100 to a third thickness T3. The oxide layer 1100 after the third plasma enhanced deposition process 1107 has good conformality, where the third thickness T3 in FIG. 11G is uniform along the top surfaces of the illustrated front side features, as well as along the sidewalls thereof. In one example, the third plasma enhanced deposition process 1107 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fourth RF power level (e.g., 75 to 550 W, such as approximately 100 W) that is less than the third power level and at a fourth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the third plasma enhanced deposition process 1107 is approximately 0.5 or less. In the above or another example, the ratio of the flow rate of the silicon precursor (e.g., SiH₄) to the flow rate of the oxygen precursor (e.g., N₂O) in the third plasma enhanced deposition process 1107 is approximately 0.0002 or more. In the above or another example, the ratio of the flow rate of the silicon precursor (e.g., SiH₄) to the flow rate of the oxygen precursor (e.g., N₂O) in the third plasma enhanced deposition process 1107 is approximately 0.0025. In the above or another example, the flow rate of the silicon precursor (e.g., SiH₄) in the third plasma enhanced deposition process 1107 is approximately 2 sccm or more and approximately 50 sccm or less, such as approximately 25 sccm.

In FIG. 11H, an in situ third plasma enhanced treatment process 1108 is performed (e.g., loop treatment or loop treat at 206 in FIG. 2) to treat the third oxide of the oxide layer 1100. The third plasma enhanced treatment process 1108 in one example is a continuation of the PECVD process that includes concurrent flows of the inert gas (e.g., helium (He), argon (Ar), etc., at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a fifth RF power level (e.g., 75 to 550 W, such as approximately 225 W) that is greater than the first and second power levels and at a fourth chamber pressure (e.g., 2 to 11 Torr, such as approximately 3 Torr). In one example, the third plasma enhanced treatment process 1108 includes substantially no flow of the silicon precursor.

In one example, additional loop deposition and loop treatment iterations are undertaken (not shown) and a final iteration is shown in FIGS. 11I and 11J. FIG. 11I shows one example, in which a fourth plasma enhanced deposition process 1109 is performed (e.g., 205 in FIG. 2) in the deposition chamber that deposits a final oxide to increases the oxide layer 1100 to a desired final thickness TF. The oxide layer 1100 after the final plasma enhanced deposition process 1109 has good uniformity where the thickness TF is uniform along the top surface and the sidewalls of the front side features. In one example, the final plasma enhanced deposition process 1109 is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a silicon precursor (e.g., silane (SiH₄) at a non-zero flow rate (e.g., approximately 2 sccm or more and approximately 50 sccm or less, such as approximately 25 sccm)) at a fifth RF power level (e.g., 75 to 550 W, such as approximately 100 W) that is less than the third power level and at a fifth chamber pressure (e.g., 2 to 11 Torr, such as approximately 3 Torr). In this or another example, a ratio of the flow rate of the silicon precursor (e.g., SiH₄) to a flow rate of the oxygen precursor (e.g., N₂O) in the final plasma enhanced deposition process 1109 is approximately 0.5 or less. In the above or another example, the ratio of the flow rate of the silicon precursor (e.g., SiH₄) to the flow rate of the oxygen precursor (e.g., N₂O) in the final plasma enhanced deposition process 1109 is approximately 0.0002 or more. In the above or another example, the ratio of the flow rate of the silicon precursor (e.g., SiH₄) to the flow rate of the oxygen precursor (e.g., N₂O) in the final plasma enhanced deposition process 1109 is approximately 0.0025. In the above or another example, the flow rate of the silicon precursor (e.g., SiH₄) in the final plasma enhanced deposition process 1109 is approximately 2 sccm or more and approximately 50 sccm or less, such as approximately 25 sccm.

In FIG. 11J, an in situ final plasma enhanced treatment process 1110 is performed (e.g., final loop treatment or loop treat at 206 in FIG. 2) in the deposition chamber to treat the final oxide of the oxide layer 1100. The final plasma enhanced treatment process 1110 in one example is a continuation of the PECVD process that includes concurrent flows of the inert gas (e.g., helium (He), argon (Ar), etc.) at a non-zero flow rate (e.g., 500 to 25,000 sccm) such as approximately 1,000 sccm), the oxygen precursor (e.g., N₂O at a non-zero flow rate (e.g., approximately 500 sccm or more and approximately 15,000 sccm or less, such as approximately 4,000 sccm)) and a nitrogen precursor (e.g., N₂ at a non-zero flow rate (e.g., approximately 500 sccm or more and approximately 25,000 sccm or less, such as approximately 1,000 sccm)) at a sixth RF power level (e.g., 75 to 550 W, such as approximately 225 W) that is greater than the first and second power levels and at a sixth chamber pressure (e.g., 2 to 11 Torr, such as approximately 3 Torr). In one example, the final plasma enhanced treatment process 1110 includes substantially no flow of the silicon precursor. In the illustrated implementation, the loop iterations provide the desired final oxide layer thickness TF and no further iterations are needed (NO at 208 in FIG. 2).

In FIG. 11K, a pumping process 1111 is performed in the deposition chamber (e.g., 210 in FIG. 2) that shuts off the various gas flows and pumps the chamber to remove any process remnants and prepares the wafer or wafers for removal from the deposition chamber. FIG. 12 shows further processing, in which a backside etch process 1200 is performed that removes the nitride layer 124 from the wafer backside while the front side protection oxide layer 1100 covers the front side nitride layer 124. Thereafter, the protection layer 1100 is removed.

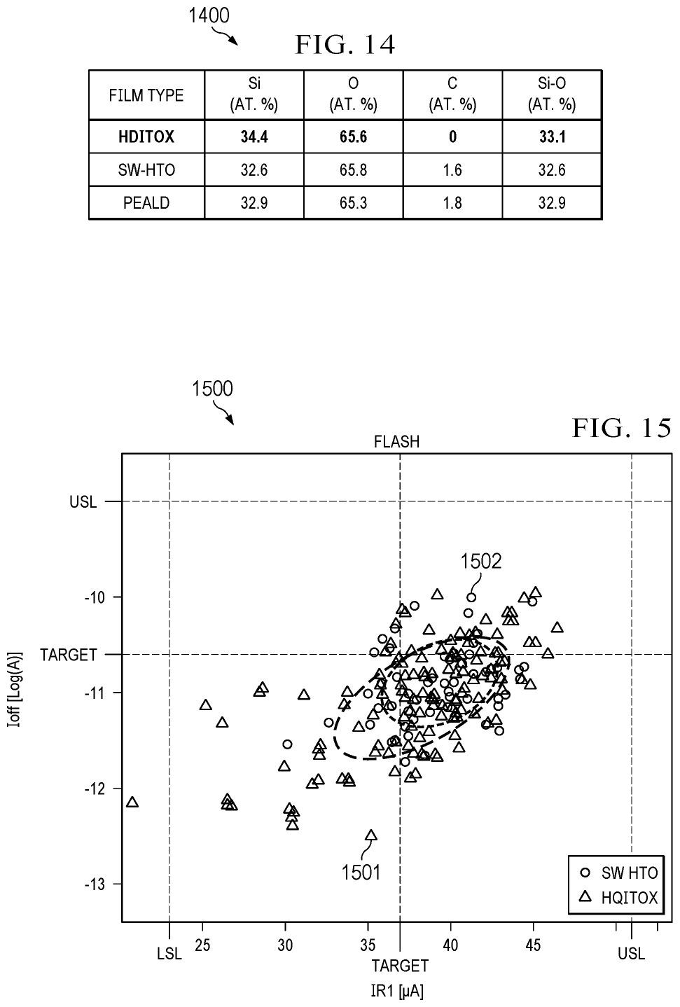

FIGS. 13-21 show example benefits of certain implementations of the described oxide layers. FIG. 13 shows a graph 1300 of Fourier-transform infrared spectroscopy (FTIR) spectra for an example HQITOX oxide layer fabricated according to an implementation of the method of FIG. 2 and FIG. 14 shows a table 1400 of X-ray photoelectron spectroscopy (XPS, also referred to as electron spectroscopy for chemical analysis (ESCA)) with atomic percentages for an example HQITOX oxide layer fabricated according to an implementation of the method of FIG. 2. FIG. 14 also shows comparative XPS atomic percentage data for another oxide formed by single wafer high temperature oxide deposition (SW-HTO) and a third oxide layer formed by plasma enhanced atomic layer deposition (PEALD). The FTIR graph 1300 in FIG. 13 shows that the example HQITOX oxide film has very little hydrogen with SiOH and Si—H peaks of almost zero. The FTIR and XPS data of FIGS. 13 and 14 show that the example HQITOX film is nearly pure oxide film with no detectable contamination in the film. In this example, the HQITOX film is fully silicon and oxygen (e.g., very little H₂, SiOH peak of almost zero). The SW-HTO and PEALD films have carbon, but the HQITOX oxide has none.

FIG. 15 shows a plot 1500 of comparative flash memory cell electrical performance including read current IR in μA vs. off state leakage current Ioff (Log A) for an example HQITOX oxide layer 1501 fabricated according to an implementation of the method 200 and a single wafer high temperature oxide layer (SW HTO) 1502. As seen in FIG. 15, the example high quality oxide layer formed according to an implementation of the method 200 has the same or similar leakage current performance as the single wafer high temperature oxide layer.

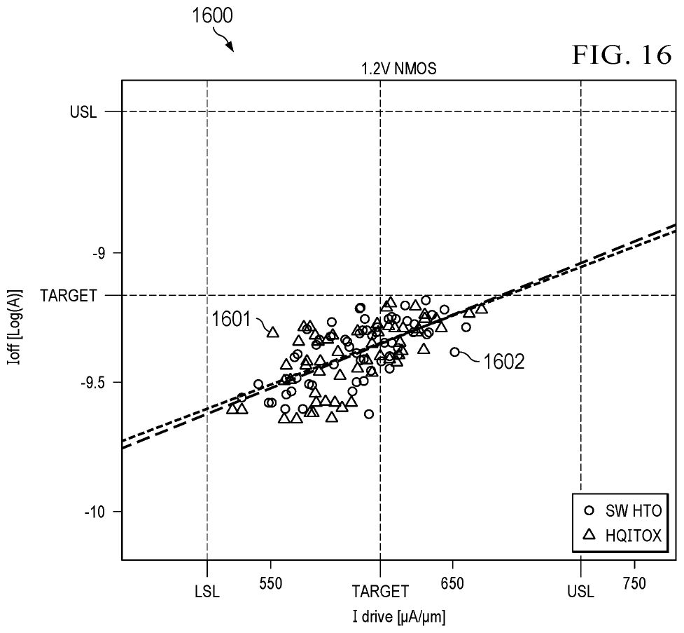

FIG. 16 shows a plot 1600 of comparative drive current performance of a 1.2 V nmos transistor with HQITOX offset spacers sidewall and cap oxide films (e.g., oxide layers 122 and 126 above) 1601 fabricated according to an implementation of the method 200 of FIG. 2 and a SW HTO layer 1602. As seen in FIG. 16, the example high quality oxide layers 122 and 126 formed according to an implementation of the method 200 have the same or similar transistor drive current and leakage current performance as a transistor that includes the single wafer high temperature oxide layers.

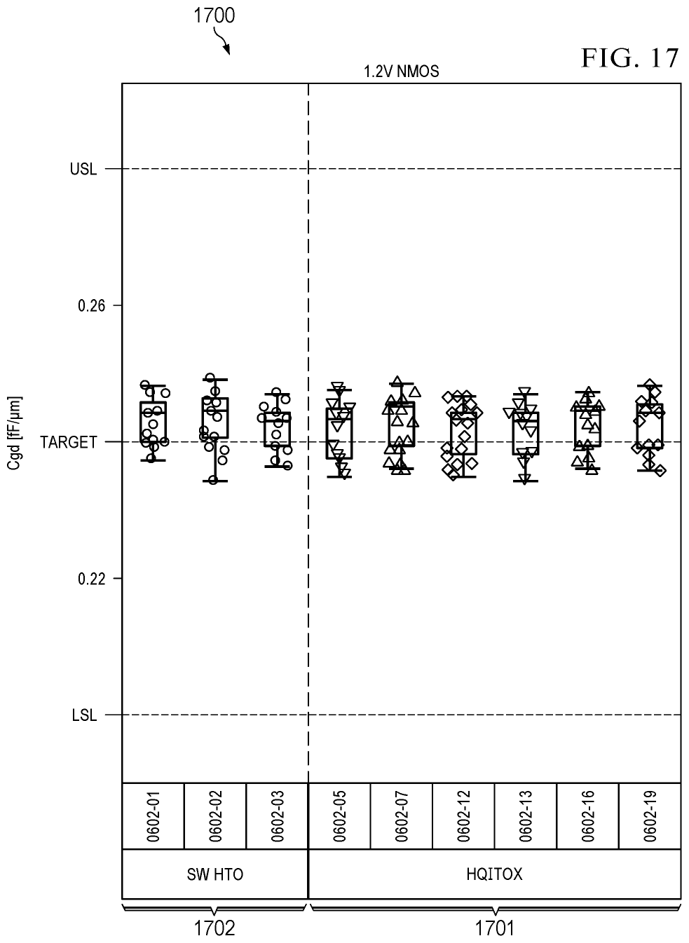

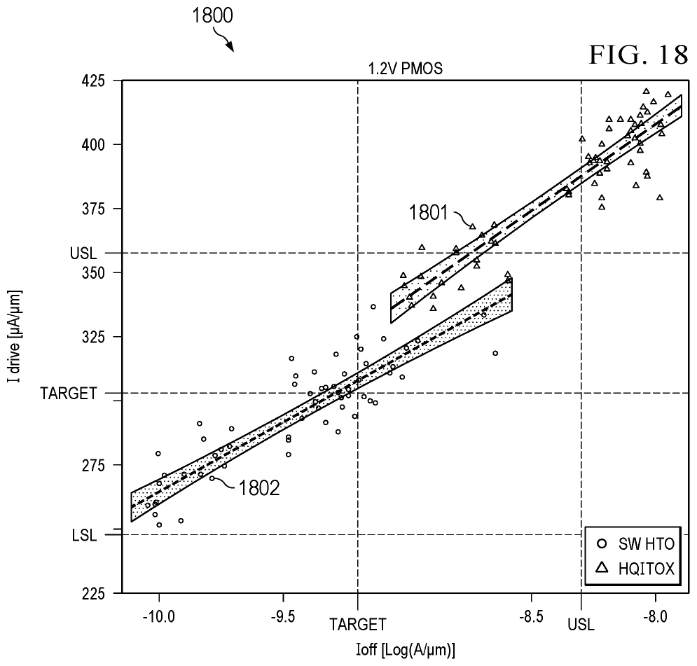

FIG. 17 shows a plot 1700 of comparative 1.2 V nmos transistor gate-drain capacitance performance for example HQITOX offset spacers sidewall and cap oxide films (e.g., oxide layers 122 and 126 above) 1701 fabricated according to an implementation of the method of FIG. 2 and SW HTO oxide layers 1702. As seen in FIG. 17, the example high quality oxide layers 122 and 126 formed according to an implementation of the method 200 have the same or similar transistor gate-drain capacitance performance as a transistor that includes the single wafer high temperature oxide layers.

FIG. 18 shows a plot 1800 of comparative 1.2 V pmos transistor drive current performance for example HQITOX offset spacers sidewall and cap oxide films (e.g., oxide layers 122 and 126 above) 1801 fabricated according to an implementation of the method of FIG. 2 and SW HTO oxide layers 1802. As seen in FIG. 18, the example high quality oxide layers 122 and 126 formed according to an implementation of the method 200 have the same or similar pmos transistor drive current and leakage current performance as a pmos transistor that includes the single wafer high temperature oxide layers.

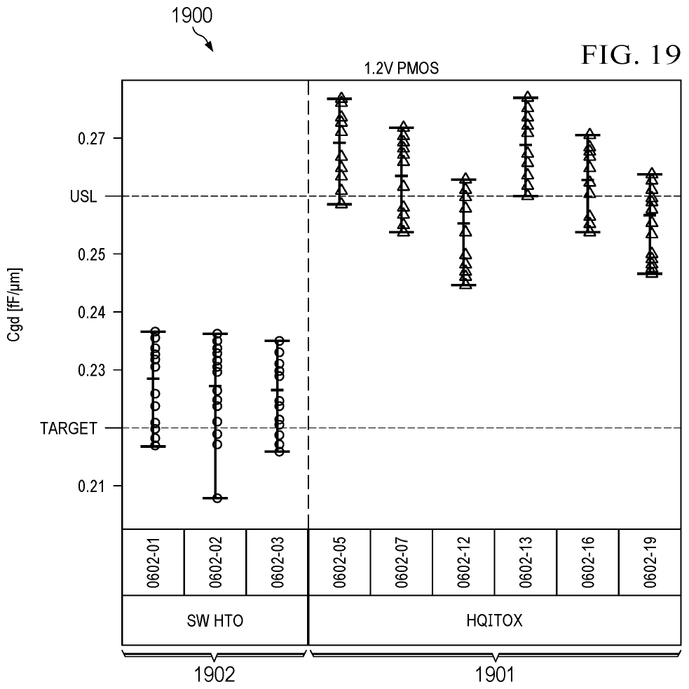

FIG. 19 shows a plot 1900 of comparative 1.2 V pmos transistor gate-drain capacitance performance for example HQITOX offset spacers sidewall and cap oxide films (e.g., oxide layers 122 and 126 above) 1901 fabricated according to an implementation of the method of FIG. 2 and SW HTO oxide layers 1902. As seen in FIG. 17, the example high quality oxide layers 122 and 126 formed according to an implementation of the method 200 have the same or similar transistor gate-drain capacitance performance as a transistor that includes the single wafer high temperature oxide layers.

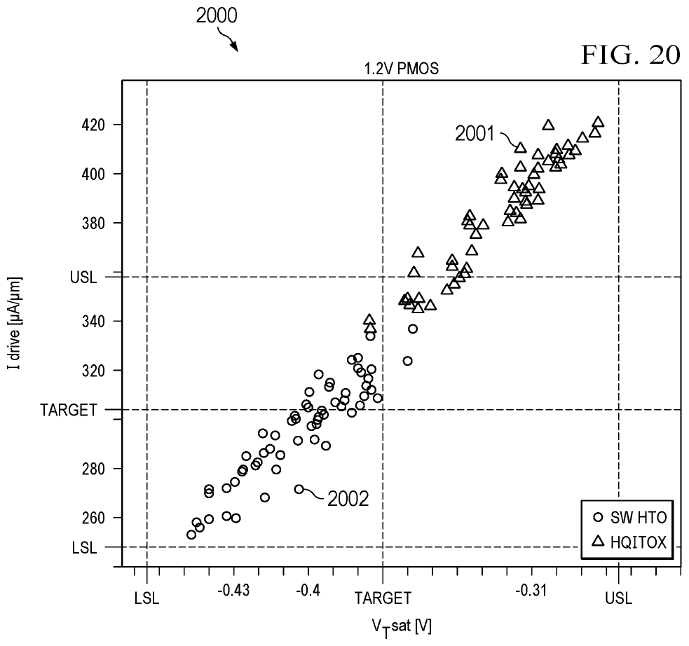

FIG. 20 shows a plot 2000 of comparative 1.2 V pmos transistor drive current performance as a function of saturation voltage V_{T}sat for example HQITOX offset spacers sidewall and cap oxide films (e.g., oxide layers 122 and 126 above) 2001 fabricated according to an implementation of the method of FIG. 2 and SW HTO oxide layers 2002. As seen in FIG. 20, the example high quality oxide layers 122 and 126 formed according to an implementation of the method 200 have the same or similar pmos transistor drive current performance as a pmos transistor that includes the single wafer high temperature oxide layers.

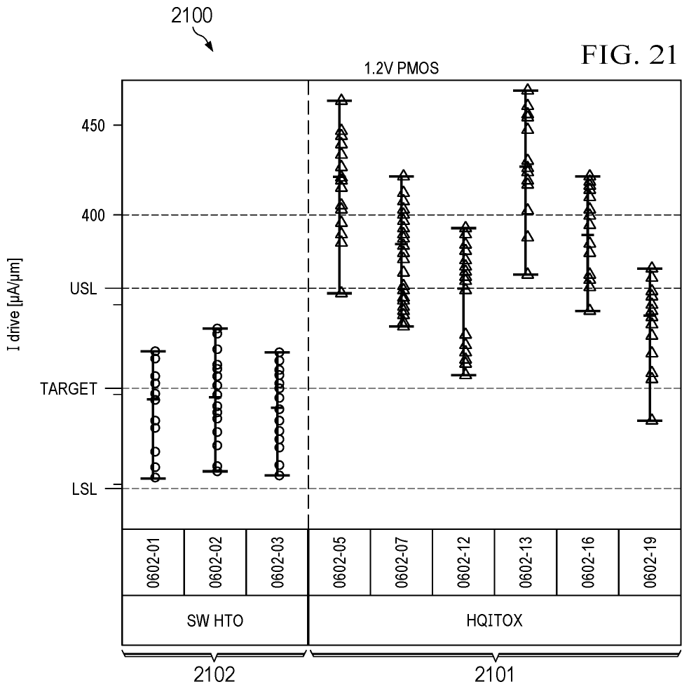

FIG. 21 shows a plot 2100 of comparative 1.2 V pmos transistor drive current performance for example HQITOX offset spacers sidewall and cap oxide films (e.g., oxide layers 122 and 126 above) 2101 fabricated according to an implementation of the method of FIG. 2 and SW HTO oxide layers 2102. As seen in FIG. 21, the example high quality oxide layers 122 and 126 formed according to an implementation of the method 200 have the same or similar pmos transistor drive current performance as a pmos transistor that includes the single wafer high temperature oxide layers.

Described example electronic devices and fabrication methods advantageously facilitate formation of oxide film layers with significantly improved, formality and uniformity as well as film quality. The disclosed examples provide utility in association with a variety of applications, including oxide layers (e.g., 122, 126) of a packaged electronic device (e.g., 100), as well as formation and use of sacrificial oxide layers (e.g., 700, 900, 1100) used as etch hard mask and/or protection layers during fabrication of a packaged electronic device. Example implementations can provide further benefits, for example, sidewall spacer and/or cap oxide layers that serve as improved diffusion barriers, for example, to mitigate diffusion of dopants or impurities from an implanted region of the semiconductor substrate (e.g., lightly doped drain and/or source/drain implant species (e.g., boron, phosphorous, etc.) of a transistor channel or source/drain region) during post-implantation thermal processing of a processed wafer, thereby advantageously mitigating the need to provide access of implantation species concentrations for a given transistor performance specification. In addition, implementations of the example oxide layers have improved quality compared with other deposition techniques, and provide advantageous performance as etch stop or hard mask layers and/or as protection layers during etch processing (e.g., reduced etch rates of the oxide film). The described examples can be implemented in a variety of different applications to form oxide layers of any desired final thickness, and the described method 200 allows adjustment for any desired number of iterations of loop deposition and loop treatment stops to achieve a desired final film thickness with good quality and conformality for use as a remaining layer in an electronic device and/or as a sacrificial layer to facilitate semiconductor fabrication processing.

The table below shows comparative oxide film processing parameters and performance including an example implementation of the HQITOX oxide layer, a single wafer high temperature oxide layer (SW-HTO), an atomic layer deposition (XP8 ALD) oxide layer, and a silicon oxide layer (SILOX).

| Items | SW-HTO tool | ALD | SILOX | HQITOX |
|---|---|---|---|---|
| Process Temp | 700° C. | 75° C. | 350° C. | 350° C. |
| Conformality | Good | Excellent | Bad | Good |
| | | (99%) | (50%) | (>95%) |
| Film Quality | OK | BAD | OK | BEST |
| Flexibility | BAD | BAD | Excellent | Excellent |
| Throughput | LOW | MEDIUM | HIGH | HIGHER |

Described example methods facilitate formation of high-quality, uniform and conformal oxide films or layers including a pretreatment step, a main deposition step followed by plasma treatment and c) loop deposition and plasma treatment. Some examples provide slow deposition rate to facilitate improved oxide film conformality, which is achieved by very low flow rates of reactive silicon precursor (e.g., SiH₄), and much higher flow of oxygen precursor (e.g., N₂O) together with very high flow of non-reactive inert gas (e.g., He, Ar, etc.). In certain examples, the resultant oxide film is densified by in situ plasma treatment after each deposition to further improve film quality, for example by reducing final film hydrogen bonds by removing the hydrogen from silicon and replacing the dangling Si bonds with more oxygen (e.g., O₂).

When used to form protection layers or etch hard mask layers, certain examples have reduced etch rates of the oxide film for diluted Hydro fluorine wet etch chemistries. The following table shows comparative etch rates for an example implementation of the above described HQITOX oxide layer, as well as oxide layers formed using single wafer high temperature oxide processing (SW-HTO) and plasma enhanced atomic layer deposition (PEALD), showing that the HQITOX film wet etch rate is significantly lower than SW-HTO & PEALD processes.

| Test | HQITOX | SW-HTO | PEALD |
|---|---|---|---|
| Etch rate | ~60 | ~240 | ~130 |
| (A/min) | | | |

The following table shows example HQITOX wet etch rate data with different wet etch chemistries and shows that the HQITOX film quality is good and consistent across different etch chemistries, which is beneficial for use as a hard mask or protection layer during semiconductor wafer processing.

| Test | 100:1 DHF | 500:1 DHF | SC1 | Hot Phos (H₃PO₄) |
|---|---|---|---|---|
| HQITOX | ~60 | ~8 | ~3 | 0.8618 |
| Etch rate | | | | |
| (A/min) | | | | |

Example implementations of a HQITOX oxide layer can beneficially serve as dopant diffusion barriers, for example, and promote retention of boron in the channel of a fabricated transistor device, such as 1.2V PMOS devices. Boron retention is supported by gate/drain overlap capacitance and drive current toggling higher. Higher boron retention allows lower LDD implant dose to match Cgd & Ion. No intrinsic degradation is seen (drive current vs threshold voltage). Drive current is higher for given leakage value, an overall benefit.

The following table shows non-limiting example process parameters for implementing the method 200.

| HQITOX (High Quality Insitu Treated Oxide) recipe | | | | | | |
|---|---|---|---|---|---|---|
| | Example recipe steps | | | | | |
| Process | Pre- | | Post | | Loop | |
| Parameters | Treatment | Deposition | Treatment | Loop Dep | Treatment | Range |
| Temperature | 350 | 350 | 350 | 350 | 350 | Range |
| Pressure | 3 | 3 | 3 | 3 | 3 | 2 to 11 |
| (Torr) | | | | | | |
| HF RF Power | 120 | 100 | 225 | 100 | 225 | 75 to 550 |
| (Watt) | | | | | | |
| SIH₄ Flow | 0 | 25 | 0 | 25 | 0 | 2 to 50 |
| (sccm) | | | | | | |
| N₂O Flow | 4000 | 4000 | 4000 | 4000 | 4000 | 500 to |
| (sccm) | | | | | | 15000 |
| He Flow | 1000 | 1000 | 1000 | 1000 | 1000 | 500 to |
| (sccm) | | | | | | 25000 |
| N₂ Flow | 0 | 0 | 1000 | 0 | 1000 | 500 to |
| (sccm) | | | | | | 25000 |
| SIH4/N₂O | 0 | 0.0025 | 0 | 0.0025 | 0 | 0.0002 to |
| Ratio | | | | | | 0.5 |
| SIH₄/He Ratio | 0 | 0.001 | 0 | 0.001 | 0 | 0.0002 to |
| | | | | | | 0.5 |
| N₂O/He Ratio | 0.4 | 0.4 | 0.4 | 0.4 | 0.4 | 0.05 to |
| | | | | | | 1.5 |
| Spacing | 550 | 550 | 550 | 550 | 550 | 300 to |
| (mills) | | | | | | 1150 |
| Number of | | | | 0 to 70 | 0 to 70 | 0 to 500 |
| treatment | | | | | | |

Modifications are possible in the described examples, and other implementations are possible, within the scope of the claims.

What is claimed is:

1. An electronic device, comprising:
an oxide layer having silicon and oxygen, the oxide layer having an atomic percentage of oxygen of greater than 64 percent by weight and an atomic percentage of carbon of less than 1 percent by weight.

2. The electronic device of claim 1, wherein the oxide layer is a transistor offset sidewall spacer oxide layer.

3. The electronic device of claim 1, wherein the oxide layer is a transistor cap oxide layer.

4. A method of fabricating an electronic device, the method comprising:
performing a plasma enhanced pretreatment process in a deposition chamber to pretreat a surface;
performing a first plasma enhanced deposition process in the deposition chamber to deposit a first oxide of an oxide layer to a first thickness on the surface;
performing an in situ first plasma enhanced treatment process in the deposition chamber to treat the first oxide of the oxide layer;
performing a second plasma enhanced deposition process in the deposition chamber to deposit a second oxide on the first oxide and increase the oxide layer to a second thickness; and
performing an in situ second plasma enhanced treatment process in the deposition chamber to treat the second oxide of the oxide layer.

5. The method of claim 4, wherein:
the pretreatment process includes concurrent flows of an inert gas and an oxygen precursor at a first power level and a first chamber pressure;
the first plasma enhanced deposition process is a plasma enhanced chemical vapor deposition (PECVD) process that includes concurrent flows of the inert gas, the oxygen precursor and a silicon precursor at a second power level and a second chamber pressure that is greater than the first chamber pressure;
the first plasma enhanced treatment process is a continuation of the PECVD process that includes concurrent flows of the inert gas, the oxygen precursor and a nitrogen precursor at a third power level that is greater than the first and second power levels and at a third chamber pressure;
the second plasma enhanced deposition process is a continuation of the PECVD process that includes concurrent flows of the inert gas, the oxygen precursor and a silicon precursor at a third power level that is less than the third power level and at a fourth chamber pressure;
the second plasma enhanced treatment process is a continuation of the PECVD process that includes concurrent flows of the inert gas, the oxygen precursor and the nitrogen precursor at a fourth power level and at a fourth chamber pressure;
a ratio of a flow rate of the silicon precursor to a flow rate of the oxygen precursor in the first plasma enhanced deposition process is approximately 0.5 or less; and
a ratio of a flow rate of the silicon precursor to a flow rate of the oxygen precursor in the second plasma enhanced deposition process is approximately 0.5 or less.

6. The method of claim 5, wherein:
the ratio of the flow rate of the silicon precursor to the flow rate of the oxygen precursor in the first plasma enhanced deposition process is approximately 0.0002 or more; and
the ratio of the flow rate of the silicon precursor to the flow rate of the oxygen precursor in the second plasma enhanced deposition process is approximately 0.0002 or more.

7. The method of claim 5, wherein:
the ratio of the flow rate of the silicon precursor to the flow rate of the oxygen precursor in the first plasma enhanced deposition process is approximately 0.0025; and
the ratio of the flow rate of the silicon precursor to the flow rate of the oxygen precursor in the second plasma enhanced deposition process is approximately 0.0025.

8. The method of claim 5, wherein:
a flow rate of the silicon precursor in the first plasma enhanced deposition process is approximately 2 standard cubic centimeters per minute (sccm) or more and approximately 50 sccm or less;
a flow rate of the oxygen precursor in the first plasma enhanced deposition process is approximately 500 sccm or more and approximately 15,000 sccm or less;
a flow rate of the silicon precursor in the second plasma enhanced deposition process is approximately 2 sccm or more and approximately 50 sccm or less; and
a flow rate of the oxygen precursor in the second plasma enhanced deposition process is approximately 500 sccm or more and approximately 15,000 sccm or less.

9. The method of claim 8, wherein:
the flow rate of the silicon precursor in the first plasma enhanced deposition process is approximately 25 sccm;
a flow rate of the oxygen precursor in the first plasma enhanced deposition process is approximately 4000 sccm;
a flow rate of the silicon precursor in the second plasma enhanced deposition process is approximately 25 sccm; and
a flow rate of the oxygen precursor in the second plasma enhanced deposition process is approximately 4000 sccm.

10. The method of claim 9, wherein:
the ratio of the flow rate of the silicon precursor to the flow rate of the oxygen precursor in the first plasma enhanced deposition process is approximately 0.0025; and
the ratio of the flow rate of the silicon precursor to the flow rate of the oxygen precursor in the second plasma enhanced deposition process is approximately 0.0025.

11. The method of claim 10, wherein:
the pretreatment process includes substantially no flow of the silicon precursor;
the first plasma enhanced treatment process includes substantially no flow of the silicon precursor; and
the second plasma enhanced treatment process includes substantially no flow of the silicon precursor.

12. The method of claim 10, wherein:
a flow rate of the nitrogen precursor in the first plasma enhanced treatment process is approximately 500 sccm or more and approximately 25,000 sccm or less; and
a flow rate of the nitrogen precursor in the second plasma enhanced treatment process is approximately 500 sccm or more and approximately 25,000 sccm or less.

13. The method of claim 12, wherein:
the flow rate of the nitrogen precursor in the first plasma enhanced treatment process is approximately 1,000 sccm; and
the flow rate of the nitrogen precursor in the second plasma enhanced treatment process is approximately 1,000 sccm.

14. The method of claim 5, wherein:
the pretreatment process includes substantially no flow of the silicon precursor;
the first plasma enhanced treatment process includes substantially no flow of the silicon precursor; and
the second plasma enhanced treatment process includes substantially no flow of the silicon precursor.

15. The method of claim 5, wherein:
a flow rate of the nitrogen precursor in the first plasma enhanced treatment process is approximately 500 sccm or more and approximately 25,000 sccm or less; and
a flow rate of the nitrogen precursor in the second plasma enhanced treatment process is approximately 500 sccm or more and approximately 25,000 sccm or less.

16. The method of claim 4, wherein:
the pretreatment process includes substantially no flow of the silicon precursor;
the first plasma enhanced treatment process includes substantially no flow of the silicon precursor; and
the second plasma enhanced treatment process includes substantially no flow of the silicon precursor.

17. The method of claim 16, wherein:
a flow rate of the nitrogen precursor in the first plasma enhanced treatment process is approximately 500 sccm or more and approximately 25,000 sccm or less; and
a flow rate of the nitrogen precursor in the second plasma enhanced treatment process is approximately 500 sccm or more and approximately 25,000 sccm or less.

18. The method of claim 4, wherein:
a flow rate of the nitrogen precursor in the first plasma enhanced treatment process is approximately 500 sccm or more and approximately 25,000 sccm or less; and
a flow rate of the nitrogen precursor in the second plasma enhanced treatment process is approximately 500 sccm or more and approximately 25,000 sccm or less.

19. The method of claim 13, wherein:
the flow rate of the nitrogen precursor in the first plasma enhanced treatment process is approximately 1,000 sccm; and
the flow rate of the nitrogen precursor in the second plasma enhanced treatment process is approximately 1,000 sccm.

20. The method of claim 4, further comprising, after the second plasma enhanced treatment process:
performing a third plasma enhanced deposition process in the deposition chamber to deposit a third oxide on the second oxide and increase the oxide layer to a third thickness; and
performing an in situ third plasma enhanced treatment process in the deposition chamber to treat the third oxide of the oxide layer.
